(19) United States
(12) Patent Application Publication
(10) Pub. No.: US 2004/0020599 A1
(43) Pub. Date: Feb. 5, 2004

(54) Treating device

(76) Inventors: Sumi Tanaka, Nirasaki-Shi (JP); Masayuki Tanaka, Nirasaki-Shi (JP); Tatsuya Handa, Nirasaki-Shi (JP)

Correspondence Address: SMITH, GAMBRELL & RUSSELL, LLP, 1850 M STREET, N.W., SUITE 800, WASHINGTON, DC, 20036, US

(21) Appl. No.: 10/416,962

(22) PCT Filed: Dec. 27, 2001
(86) PCT No.: PCT/JP01/11570

(30) Foreign Application Priority Data
Dec. 27, 2000 (JP) 2000-398507
Mar. 9, 2001 (JP) 2001-66196

(51) Int. Cl. H01L 21/306

(52) U.S. Cl. 156/345.29; 156/345.51

(57) ABSTRACT

A processing container, a pedestal for mounting wafer W, a processing gas feeder for feeding a processing gas to the front surface of the wafer W, an annular substrate-holding member for holding the wafer W, a purge gas feeder for feeding purge gas into a space formed at the backside surface side of the wafer W, a purge gas flow path for upwardly inducing a purge gas inside said space from between the wafer W and said substrate holding member, and a gas discharge mechanism for discharging said purge gas in a case that a pressure in said space becomes higher than a pressure outside said space within said processing container by a predetermined value. Further, a susceptor is composed of a material with thermal radiation transmissivity equal to or lower than dissimilar members such as temperature sensors contained in the susceptor.

### FIELD OF THE INVENTION

The present invention relates to a processing apparatus for processing substrates-to-be-processed such as semiconductor wafers. The present invention specifically relates to a processing apparatus wherein substrates-to-be-processed are processed by supplying a processing gas, applying heat, forming films, etc.

### BACKGROUND OF THE INVENTION

In order to form wiring patterns on a semiconductor wafer (hereinafter referred to as, simply, a wafer) as an object, or in order to fill in holes between the wiring patterns, a thin film is formed on a wafer by depositing metals or metallic compounds such as W (tungsten), WSi (tungsten silicide), Ti (titanium), TiN (titanium nitride) and TiSi (titanium silicide) in a manufacturing process of semiconductors.

W films, among the films formed with these metals or metallic compounds, is formed by a CVD film deposition technology using a processing gas, e.g. such as WF₆ (tungsten hexafluoride) and SiH₄ (silane) or SiH₂Cl₂ (dichlorosilane)

FIG. 1 illustrates an example of a CVD film formation apparatus for depositing the above-mentioned W films. The CVD film formation apparatus is provided with a chamber 101, a pedestal 102 provided inside the chamber 101 for mounting wafers, a showerhead 104 for providing a processing gas to a processing space 103 defined on the front surface side of a wafer mounted on the pedestal 102, a thermal radiation mechanism 105 provided below the pedestal 102 for heating a wafer mounted on the pedestal 102 by releasing thermal radiation, and clamp ring 106 for depressing and holding a wafer onto the pedestal 102. In a suchlike apparatus, film formation for the W films is processed by providing the aforementioned processing gas from the showerhead 104 to the processing space 103 defined on the front surface side of the wafer while a wafer is mounted and held by the clamp ring 106 on the pedestal 102 and heated by the thermal radiation mechanism 105. At this occasion, a purge gas is provided from the back surface side of the wafer, as indicated by an arrow in the drawings, to prevent the processing gas from entering through a space between the clamp ring 106 and the wafer etc. consequently preventing film formation around the rim or on the backside surface of the wafer.

However, if the processing space 103 of said CVD film formation apparatus is rapidly depressurized after the film formation process etc. so that the processing time would be cut down to enhance throughput, members such as the clamp ring 106 might become flip-flop as a result of fast flow of the purge gas from between a wafer and the clamp ring 106 toward the processing space 103 due to a pressure differential immediately increased between the processing space 103 and the purge gas provided from the back surface side of a wafer. Thus it has been a concern that particles and members could be damaged if the members such as the clamp ring 106 become flip-flop. A decrease of throughput has also been a concern because said CVD apparatus takes time for a step-by-step depressurization of the processing space 103 instead of rapid depressurization.

The present invention has been accomplished in consideration of these factors, and one of the purposes of this invention is to provide a processing apparatus in which a processing gas is completely prevented from entering the back surface side of a substrate and also a rapid depressurization of a processing space rarely causes any problems.

Further, in order to form wiring patterns, electrodes, etc. on a front surface of an object such as a semiconductor wafer, a thin film is formed by depositing metals or metallic compounds such as W (tungsten), WSi (tungsten silicide), Ti (titanium), TiN (titanium nitride) and TiSi (titanium silicide) generally in a manufacturing process of semiconductor integrated circuits. As an apparatus to form these kinds of thin films, a processing apparatus of a lamp-heating type, for example, is applied.

In a case that a film formation is performed by this kind of thermal CVD apparatus, a semiconductor wafer W is mounted on a susceptor 401 located in the center of the apparatus, as shown in FIG. 2, and the semiconductor wafer W is held by clamp ring 402.

Corresponding to the number of lifter pins 403, the same number of pin holes (relief holes) 404 (e.g. three as shown in FIG. 3) are formed through said susceptor 402, enabling the lifter pins 403 for a semiconductor wafer to be shifted up and down. These lifter pins 403 are installed on arms which are supported by a lift shaft constructed liftable by means of an actuator, not shown. Thus the lifter pins 403 are shifted up and down through said lifter pin holes 404.

Said susceptor 401 is maintained at a predetermined temperature by a heating lamp 405 comprising halogen lamps etc. positioned below so that the heat can be evenly transferred to the surface of a semiconductor wafer through the susceptor 401.

In fact, however, temperature distribution on a semiconductor wafer is not always even in conventional cases due to various obstacles. In consideration of the fact that uneven temperature distribution of a semiconductor wafer obstructs thin films to be evenly formed on a semiconductor wafer, the issue is to make temperature distribution of a semiconductor wafer as even as possible by solving those various obstacles.

The following are possible factors which cause uneven temperature distribution as described above.

Firstly, the susceptor 401 might occasionally contain dissimilar members made of materials which are different from a susceptor material, for example a temperature sensor composed of sheathed thermocouple (TC) etc., and when these dissimilar members are contained, uneven temperature distribution is anticipated as a result of different thermal radiation transmissivities between the susceptor 401 and the dissimilar members.

Since said susceptor 401 generates heat by absorbing lamp light, especially wavelengths (heat wave) such as infrared wavelengths from the heating lamp 405, the susceptor 401 with a high thermal radiation transmissivity would have poor absorption of wavelengths such as infrared wavelengths, and thus the temperature of the susceptor 401 becomes low. The thermal radiation transmissivity of said susceptor 401 as a whole normally is even, and consequently the temperature distribution also becomes even.

However, in a case that the susceptor 401 contains dissimilar members, such as a temperature sensor, with different thermal radiation transmissivities, the greater the difference of the thermal radiation transmissivities is, the more likely the temperature differences by area within the susceptor 401 are caused, and therefore the temperature distribution of the susceptor 401 is anticipated uneven.

For instance, in a thermal CVD apparatus for handling semiconductor wafers with a diameter of 200 mm, a temperature sensor (TC) may be inserted into the susceptor 401 in a position which is relatively near to the edge part in order to control the temperature of the semiconductor wafers.

Moreover, in a thermal CVD apparatus for handling larger semiconductor wafers with a diameter of 300 mm, a second temperature sensor (TC) may be inserted into the susceptor 401 in deeper position from the edge part close to the center, due to inadequacy of temperature control only by a temperature sensor at the edge part of the susceptor 401. To be more precise, as shown in FIG. 4., a temperature sensor 406 is inserted into the susceptor 401 to a position of approximately 15 mm from the edge part and also a second temperature sensor 407 is inserted into the susceptor 401 to a position of approximately 120 mm from the edge part close to the center so that the temperature of a semiconductor wafer may be controlled by the two temperature sensors 406 and 407.

In conventional cases, since the susceptor 401 containing dissimilar members such as these temperature sensors is made of a material with a high thermal radiation transmissivity such as white-colored AlN (aluminum nitride)-based ceramics for example, the difference in the thermal radiation transmissivities becomes enormous by the susceptor 401 containing a temperature sensor 406 which is made of a material with a low thermal radiation transmissivity, which has become one of the reasons to cause uneven temperature distribution on a semiconductor wafer. Particularly in the thermal CVD apparatus for handling semiconductor wafers with a diameter of 300 mm, differences in the thermal radiation transmissivities have high effects on the temperature distribution on a semiconductor wafer due to the facts that two temperature sensors 406 and 407 are contained and one sensor out of these two is positioned close to the center of the susceptor 401.

Secondly, the temperature distribution may become uneven as a result of a difference between the susceptor 401 and the clamp ring 402 in thermal radiation transmissivity. In this case, the temperature of the clamp ring 402 becomes lower than the temperature of the susceptor 401, in spite of the fact that both are exposed by thermal radiation from the same heat source, since the clamp ring 402 is ring-shaped and smaller in dimension than the susceptor 401. In addition, the temperature distribution becomes uneven due to the heat of the rim part of a semiconductor wafer absorbed by the clamp ring 402 for the clamp ring 402 has contact only with the rim part of a semiconductor wafer.

FIG. 5 shows an made of of measurement of the in-plane temperature of a semiconductor wafer, wherein both the clamp ring 402 and the susceptor 401 are made of white-colored AlN (aluminum nitride)-based ceramics with a high thermal radiation transmissivity and heat is applied to the semiconductor wafer by the thermal radiation from the heating lamp 405 through the susceptor 401. In this case, processing gases Ar, H₂, N₂, etc. other than film deposition gases are induced into a processing container to set up the pressure substantially at 10600 Pa, and the temperature of a semiconductor wafer W is controlled to stay at 445° C. In addition, a thermocouple is provided on the semiconductor wafer to measure the temperature on the wafer. In the said FIG. 5, the horizontal axis shows measurement positions given that the center position of the semiconductor wafer with a diameter of 300 mm is 0, and the vertical axis shows temperatures measured at these measurement positions. Also, the line with black triangles shows in-plane temperatures of the semiconductor wafer and the white triangles show temperature of the clamp ring 402.

The result of the experiment shows that the in-plane temperature distribution is uneven wherein the temperatures (white triangles) of the clamp ring 402 are lower than the temperatures of the center part or peripheral parts of the center part of the semiconductor wafer (−100 mm to 100 mm) and the temperatures of the rim part of the semiconductor wafer (100 mm to 150 mm and −100 mm to −150 mm) are lower than the temperatures of the center part or peripheral parts of the center part of the semiconductor wafer. In this way in conventional cases, the clamp ring 402 also is composed of a material with a high thermal radiation transmissivity in the same manner as the susceptor 401 to cause temperature differences as a result of dimensional differences of areas exposed by thermal radiation, which has become another reason to cause uneven temperature distribution on a semiconductor wafer.

Thirdly, the temperature distribution may become uneven as a result of pin holes provided through the susceptor 401. For instance, FIG. 3 shows three lifter pin holes 404 for the lifter pins 403 spaced at equal intervals on a concentric circle on the rim part of the susceptor 401, and thermal radiation from the heating lamp 405 can be transmitted through these lifter pin holes 404. Therefore, a temperature distribution at the rim part of the susceptor 401 may become uneven when the interval between the lifter pin holes 404 is wide.

Accordingly, in consideration of these problems, another purpose of the present invention is to provide a processing apparatus which is able to improve evenness of temperature distribution of a semiconductor wafer and thus improve evenness of thickness distribution of a thin film formed on an object such as a semiconductor wafer.

### DISCLOSURE OF THE INVENTION

To solve the above-described problems, a processing apparatus characterized by comprising: a processing container for processing a substrate with a processing gas; a pedestal positioned inside said processing container, for mounting a substrate; a processing gas feeder for feeding a processing gas to the front surface of said substrate inside said processing container; an annular substrate-holding member for holding said substrate on said pedestal by holding down a rim of said substrate; a purge gas feeder for feeding a purge gas to a space formed at the back surface side of said substrate; a purge gas flow path defined by said substrate holding member, for introducing said purge gas upward from said space; and a gas discharge mechanism for discharging said purge gas from said space in a case that a pressure in said space becomes higher than a pressure outside said space within said processing container by a predetermined value, is provided according to a first viewpoint of the present invention.

Furthermore, according to a second viewpoint of the present invention, a processing apparatus characterized by comprising: a processing container for processing a substrate with a processing gas; a pedestal positioned inside said processing container, for mounting a substrate; a processing gas feeder for feeding a processing gas to a first space formed at the front surface side of said substrate; an annular substrate-holding member for holding said substrate by holding down a rim of said substrate; a purge gas feeder for feeding a purge gas to a second space formed at the back surface side of said substrate; a purge gas flow path defined by said substrate holding member, for introducing said purge gas from said second space to said first space; an exhaust means for exhausting said first space through a third space formed below said first space and outside said second space; and a gas discharge mechanism for discharging said purge gas to said third space in a case that a pressure in said second space becomes higher than a pressure in said first space by a predetermined value, is provided.

In the present invention, in a case that a pressure in a said space becomes higher than a pressure outside said space within the processing container by a predetermined value, by comprising the gas discharge mechanism for discharging said purge gas from said space, a processing gas can be prevented from entering said space by said purge gas when said substrate is processed, and also said purge gas can be discharged from said space by said gas discharge mechanism when said processing container is depressurized, and due to no enormous pressure differential developed between the inside and the outside of said space within said processing container, problems such as flip-flop of said substrate holding member can be prevented.

Preferably, the processing apparatus according to said first and second viewpoints further comprises a support member for holding an outer circumference of said substrate holding member, and said purge gas flow path includes a first flow path passing between said substrate holding member and said substrate and a second flow path passing between said substrate holding member and said supporting member. Consequently, a processing gas can be assuredly prevented from escaping to the rim and the backside surface of said substrate at film formation.

The processing apparatus according to said first viewpoint can be structured in which said gas discharge mechanism has a valve for opening a discharge hole in a case that a pressure in said space becomes higher than a pressure outside said space within said processing container by a predetermined value.

Further, the processing apparatus according to said second viewpoint can be structured in which said gas discharge mechanism is formed to communicate through said third space and said second space and has a discharge hole for discharging said purge gas and a valve for opening said discharge hole in a case that a pressure in said second space becomes higher than a pressure in said third space by said predetermined value. Said third space is depressurized in preference to said first space, and by this constitution, a pressure in said second space can be assuredly prevented from becoming higher than a pressure in said first space by a predetermined value at depressurization.

In these case, said gas discharge mechanism preferably discharges said purge gas before the pressure differential between the inside and the outside of said space within said processing container or the pressure differential between said second space and said third space reaches a value for said substrate holding member to be lifted by said purge gas flowing through said purge gas flow path. Consequently, said purge gas can assuredly be discharged before said substrate holding member is lifted and becomes flip-flop at a rapid depressurization.

Further, said gas discharge mechanism preferably discharges said purge gas after pressure loss caused by flow of said purge gas from said space or from said second space is exceeded by the pressure differential between the inside and the outside of said space within said processing container or the pressure differential between said second space and said third space, when said substrate is processed. Consequently, discharge of said purge gas from said space or said second space can be prevented when said substrate is processed.

Further, said gas discharge mechanism is preferably switched to an open condition from a closed condition when the pressure differential between said second space and said first space reaches a value between a value of pressure loss caused by flow of said purge gas from said space at substrate processing and a value for said substrate holding member to be lifted by said purge gas flowing through said purge gas flow path. Consequently, said purge gas can assuredly discharged before said substrate holding member is lifted and becomes flip-flop at rapid depressurization and also discharge of said purge gas from said space or said second space can be prevented when said substrate is processed.

The processing apparatus according to said first and second viewpoint can further comprise a gas introducing mechanism for introducing atmosphere outside said space within said processing container into said space in a case that a pressure outside said space within said processing container becomes higher than a pressure inside said space by a predetermined value, or for introducing atmosphere inside said third space into said second space in a case that a pressure in said third space becomes higher than a pressure in said second space by a predetermined value. Consequently, damages to members as a result of extremely high pressure differential within said processing container, developed by malfunction or breakdown or the processing apparatus, can be prevented.

In this case, said gas introducing mechanism can be structured by comprising: an introducing hole for introducing atmosphere outside said space within said processing container into said space; and a valve for opening said introducing hole in a case that a pressure outside said space within said processing container is higher than a pressure in said space by said predetermined value, or comprising: an introducing hole for introducing atmosphere in said third space into said second space; and a valve for said introducing hole to be open in a case that a pressure in said third space is higher than a pressure in said second space by said predetermined value.

The present invention according to a third viewpoint provides a thermal processing apparatus wherein an object is mounted on a acceptance heating element inside a processing container supplied with a processing gas and then said object is heated by thermal radiation from a heat source through said acceptance heating element, characterized in that said acceptance heating element is composed of a material with thermal radiation transmissivity equal to or lower than those of dissimilar members contained in said acceptance heating element. According to the present invention, in a case that dissimilar members with low thermal radiation transmissivity such as temperature sensors are contained in a susceptor as the acceptance heating element for example, by composing the susceptor with a material with thermal radiation transmissivity equal to or lower than those of said dissimilar members, or by composing the acceptance heating element with black-colored AlN-based ceramics with low thermal radiation transmissivity, the temperature differential between the dissimilar members with low thermal radiation transmissivity and the susceptor can be decreased, and thus impacts on the temperature distribution on the susceptor caused by containing dissimilar members can be reduced, and evenness of the in-plane temperature distribution of a semiconductor wafer can be improved.

Further, in the thermal processing apparatus wherein an object is mounted on a acceptance heating element inside a processing container supplied with a processing gas and then said object is heated by thermal radiation from a heat source through said acceptance heating element while a ring-shaped object pressing member holds this object by the rim part, since said object pressing member is composed of a material with lower thermal radiation transmissivity than said acceptance heating element, the temperature differential between the acceptance heating element and the object pressing member can be decreased, and thus the object pressing member can be prevented from absorbing heat from a semiconductor wafer. Consequently, the in-plane temperature differential of a semiconductor wafer caused as a result of a difference between heat receiving areas of the acceptance heating element such as a susceptor and an object can be decreased, and thus evenness of the in-plane temperature distribution of a semiconductor wafer can be improved.

Further, by composing the object pressing member whose temperature is likely to relatively lower than the acceptance heating element with black-colored AlN-based ceramics with low thermal radiation transmissivity, the temperature differential between the acceptance heating element such as a susceptor and the object pressing member can be decreased, and thus evenness of the in-plane temperature distribution of a semiconductor wafer can be improved. In this case, the thinner the susceptor thickness becomes, the more increased the thermal radiation transmissivity is. However, by composing the susceptor also with black-colored AlN-based ceramics with low thermal radiation transmissivity, the thinned susceptor can have low thermal radiation transmissivity and high heat rate, and thus the temperature differential between the susceptor and the object pressing member can be decreased. Consequently, evenness of the temperature distribution of the whole surface of a semiconductor wafer can further be improved.

Further, by forming relief holes, which enable a plurality of supporting members for supporting said object to be mounted on said acceptance heating element to come in and out, and holes having the same shape thereof on said acceptance heating element in a manner that each hole is aligned and equally spaced on a concentric circle, thermal radiation from a heat source is evenly transmitted through each hole since intervals between each hole become narrower and also each hole is equally spaced. Consequently, compared to a case that thermal radiation is transmitted only through the relief holes, evenness of temperature distribution of the rim part of the acceptance heating element such as a susceptor can further be improved. Consequently, evenness of in-plane temperature distribution of a semiconductor wafer can be improved.

### BRIEF DESCRIPTION OF THE DRAWINGS

FIG. 1 is a diagrammatic cross-sectional view of a conventional CVD film formation apparatus.

FIG. 2 is a simplified cross-sectional view of a susceptor periphery in a conventional thermal processing apparatus.

FIG. 3 is a drawing illustrating a susceptor having lifter pin holes formed therethrough in a conventional thermal processing apparatus.

FIG. 4 is a drawing illustrating a susceptor containing two temperature sensors in a conventional thermal processing apparatus.

FIG. 5 is a graph showing correlations between in-plane temperatures of a semiconductor wafer and positions of the temperature measurement when a film formation is processed by a conventional thermal processing apparatus.

FIG. 6 is a cross-sectional pattern diagram of a CVD film formation apparatus according to an embodiment of the present invention, illustrating an arrangement of a wafer W mounted on a pedestal.

FIG. 7 is a cross-sectional pattern diagram of the CVD film formation apparatus shown in FIG. 6, illustrating an arrangement of a wafer W supported on lift pins.

FIG. 8 is an enlarged view illustrating purge gas flows around a clamp ring of the CVD film formation apparatus shown in FIG. 6.

FIG. 9A is a longitudinal sectional view of a gas discharge mechanism.

FIG. 9B is a longitudinal sectional view of a gas introducing mechanism.

FIG. 10 is an enlarged cross-sectional view illustrating the gas discharge mechanism discharging a purge gas.

FIG. 11 is an enlarged cross-sectional view illustrating the gas introducing mechanism inducing atmosphere from a exhaust space.

FIG. 12 is a cross-sectional view of the CVD film formation apparatus shown in FIG. 6, taken along line A-A.

FIG. 13 is a drawing showing an example of a modification of the gas discharge mechanism.

FIG. 14 is a drawing showing another example of a modification of the gas discharge mechanism.

FIG. 15 is a cross-sectional view showing a structure of a thermal processing apparatus according to an embodiment of the present invention.

FIG. 16 is an enlarged cross-sectional view showing a rim part of a susceptor shown in FIG. 15.

FIG. 17 is a drawing illustrating a susceptor composed of black-colored AlN (aluminum nitride)-based ceramics and a temperature sensor contained therein according to an embodiment of the present invention.

FIG. 18 is a drawing illustrating a susceptor composed of black-colored AlN-based ceramics and temperature sensors contained therein according to an embodiment of the present invention.

FIG. 19 is a graph showing correlations between wavelengths transmitted through white-colored AlN-based ceramics and through black-colored AlN-based ceramics and transmissivities of the wavelengths.

FIG. 20 is a graph showing a film thickness distribution wherein a film disposition is processed and the film thickness is measured at positions on a temperature sensor of a semiconductor wafer. The line with black squares shows a film thickness distribution of a susceptor composed of white-colored AlN-based ceramics, and the line with black circles shows a film thickness distribution of a susceptor composed of black-colored AlN-based ceramics.

FIG. 21 is a drawing illustrating a susceptor composed of white-colored AlN-based ceramics and clamp ring composed of black-colored AlN-based ceramics according to another embodiment of the present invention.

FIG. 22 is a graph showing correlations between in-plane temperatures of a semiconductor wafer and positions of the temperature measurement when a film formation is processed by a thermal processing apparatus according to another embodiment of the present invention.

FIG. 23 is a drawing illustrating a susceptor having lifter pin holes and other holes shaped as these lifter pin holes.

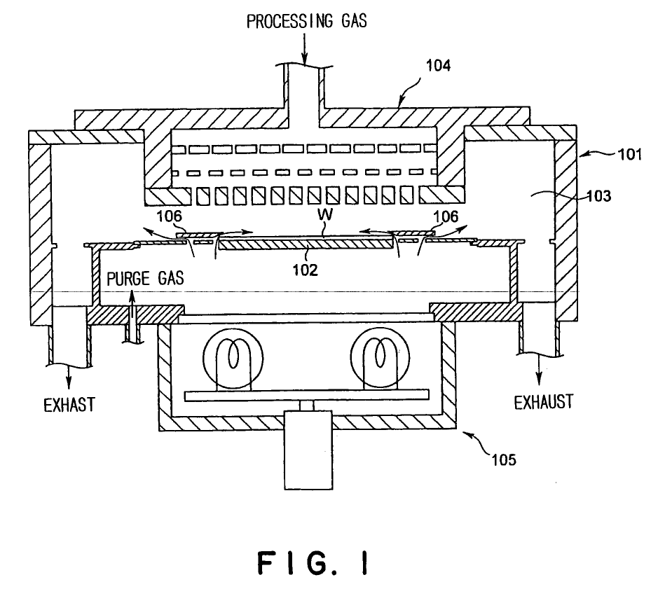

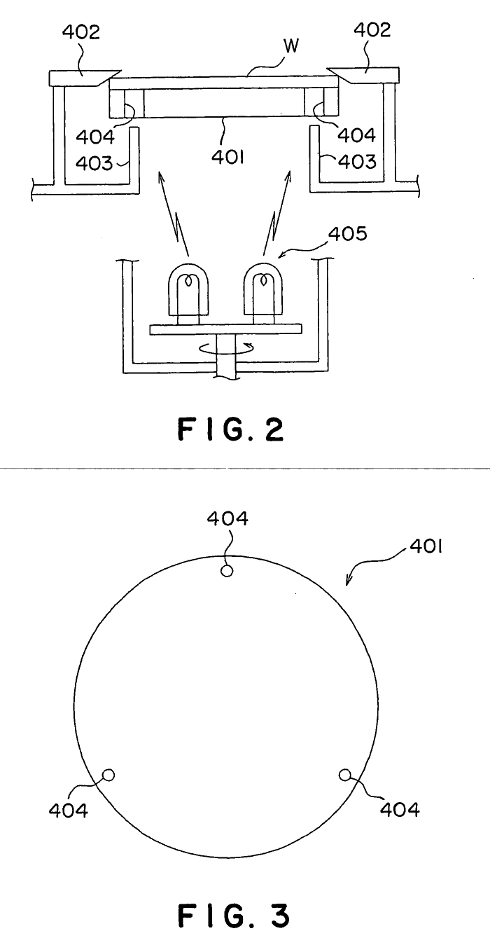

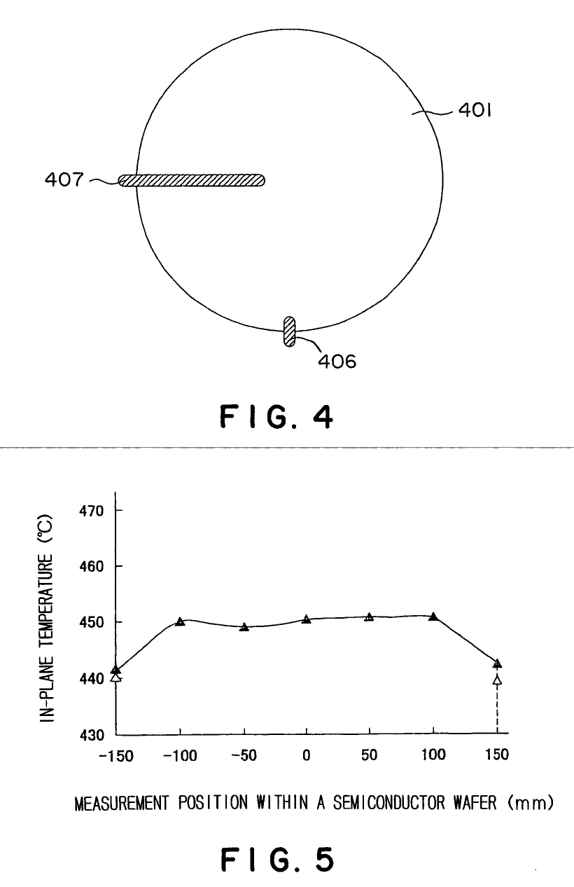

### BEST EMBODIMENTS FOR REALIZING THE INVENTION

Hereinafter, embodiments of the present invention will be specifically explained with reference to the accompanying drawings.

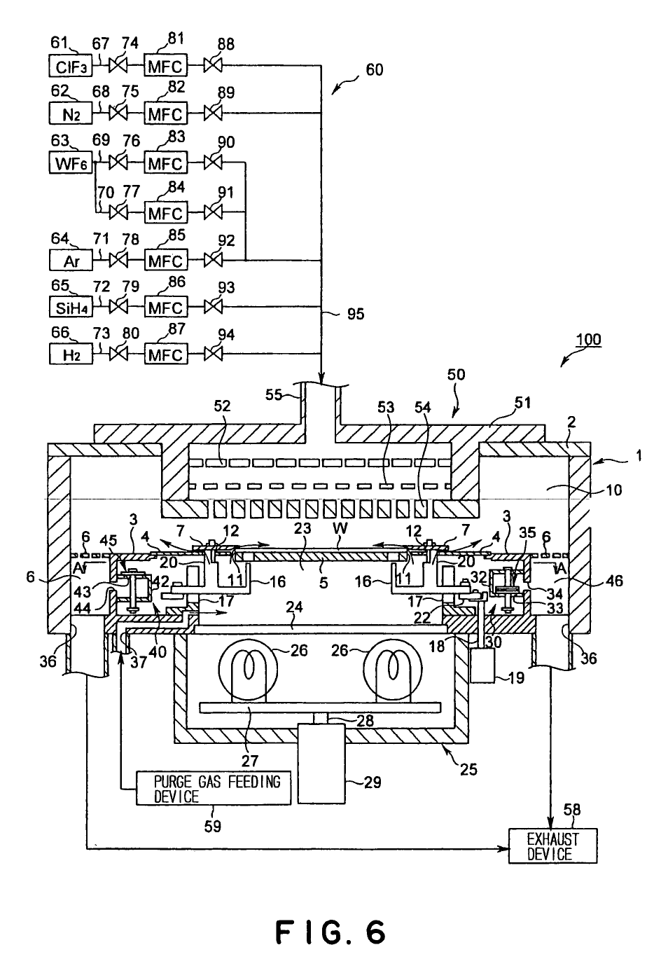

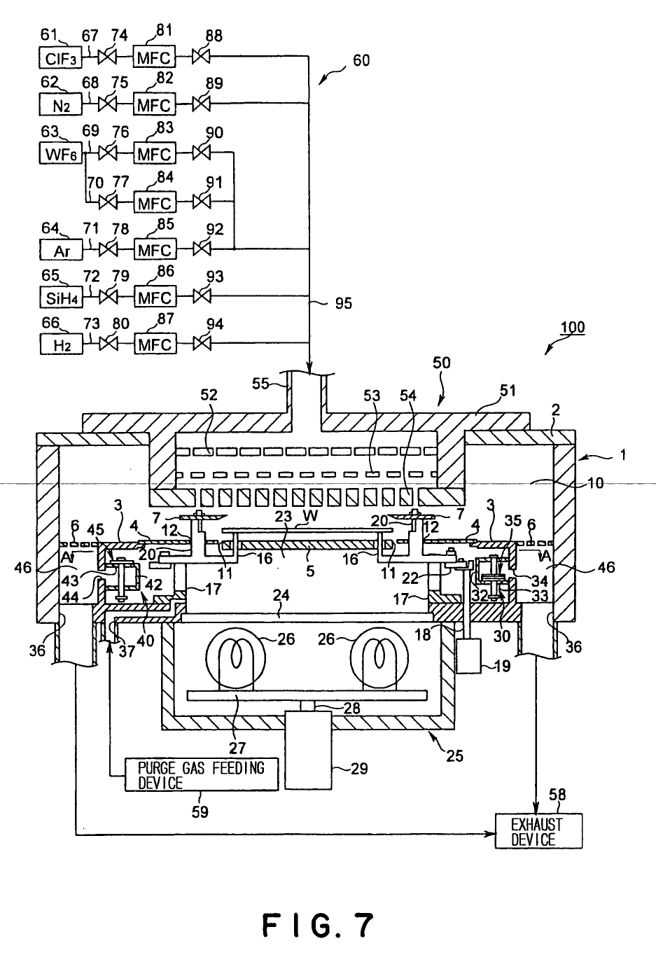

FIG. 6 and FIG. 7 are cross-sectional pattern diagrams of a CVD film formation apparatus according to an embodiment of the present invention, in which FIG. 6 shows an arrangement of a semiconductor wafer W (hereinafter referred to as, simply, a wafer W) as a substrate mounted on a pedestal and FIG. 7 shows an arrangement of a wafer W supported on lifter pins. This CVD film formation apparatus functions to form W films.

As shown in FIG. 6 and FIG. 7, a CVD film formation apparatus 100 comprises a chamber 1 which is cylindrically formed and made of aluminum etc. for example, with a lid 2 provided thereon. Inside the chamber 1, a covered cylindrical shield base 3 with an opening provided at ceiling area thereof is built up from the bottom part of the chamber 1. Annular attachment 4 is positioned along the opening provided at the ceiling area of the shield base 3, and a pedestal 5 for mounting a wafer W is provided and supported by the attachment 4. A gap 11 is provided between the attachment 4 and the pedestal 5, and a clamp ring 7 to be hereinafter described is provided above the gap 11. This attachment 4 additionally functions as a support member for supporting the outer circumference side of the clamp ring 7. Also a baffle plate 6 having numbers of hole portions is provided between a outer wall of the shield base 3 and a inner wall of the chamber 1. A processing gas is supplied from a showerhead 50 to be hereinafter described into a processing space (a first space) 10 defined inside the thus-structured chamber 1 and in the front-surface side of a wafer W mounted on the pedestal 5. Below the processing space 10, a backside space (a second space) 23 is defined, surrounded by the shield base 3, the attachment 4 and the pedestal 5. Outside the backside space 23, an exhaust space (a third space) 46 is defined, surrounded by the chamber 1, the shield base 3 and the baffle plate 6.

To lift a wafer W from the pedestal 5, for example three of lift pins 16 (FIG. 6 shows two out of the three) are provided below the pedestal 5 in the backside space 23 and supported by a pushup stick 18 by way of a holding member 22 wherein the pushup stick 18 is joined to an actuator 19. The lift pins 16 are composed of a heat-ray transmissive material, for example silicon dioxide, ceramics such as AlN.

Further, a supporting member 20 is monolithically formed with the lift pins 16, and this supporting member 20 pierces through hole portions 12 of the attachment 4 to join the annular clamp ring 7 provided above the pedestal 5 linked by springs (not shown). The internal circumferential part of the lower surface of the clamp ring 7 has a taper to become radially-inwardly thinner in thickness to land on a wafer W for the internal circumference part to be directly contacted to the outer circumferential part of the wafer W and hold the wafer W downward by taking advantages of weight of the clamp ring 7 itself and the spring forces in order to hold the wafer W on the pedestal 5.

Due to the structure in this way, the lift pins 16 and the clamp ring 7 are moved up and down in a unified manner by the actuator 19 which moves the pushup stick 18 up and down. Concerning the lift pins 16 and the clamp ring 7, when a wafer W is transferred, the lift pins 16 are moved up to be projected for a predetermined length from the pedestal 5 (Refer to the FIG. 7), and when a wafer W is mounted on the pedestal 5, the lift pins 16 come down into the pedestal 5 and are moved down to a position for the clamp ring 7 to directly contact and support the wafer W (Refer to FIG. 6).

At the bottom of the chamber 1 directly underneath the pedestal 5, a transmission window 24 composed of heat-ray transmissive material such as quartz (silicon dioxide) is installed airtight, and below the transmission window 24, a box-shaped heat chamber 25 is provided surrounding the transmission window 24. Inside the heat chamber 25, lamps 26 are installed on a rotating table 27 which also functions as a reflector, and this rotating table 27 can be rotated by a rotating motor 29 which is provided, linked via a rotating shaft 28, at the bottom of the heat chamber 25. Consequently, thermal radiation emitted from the lamps 26 transmit through the transmission window 24 and irradiate the lower surface of the pedestal 5 for heating. Above the transmission window 24, a reflector 17 which is tubular along the outer circumference of the transmission window 24 is provided, and the internal circumferential surface of this reflector 17 is mirror-finished for efficiently conducting thermal radiation by reflection from the lamps 26 to the pedestal 5.

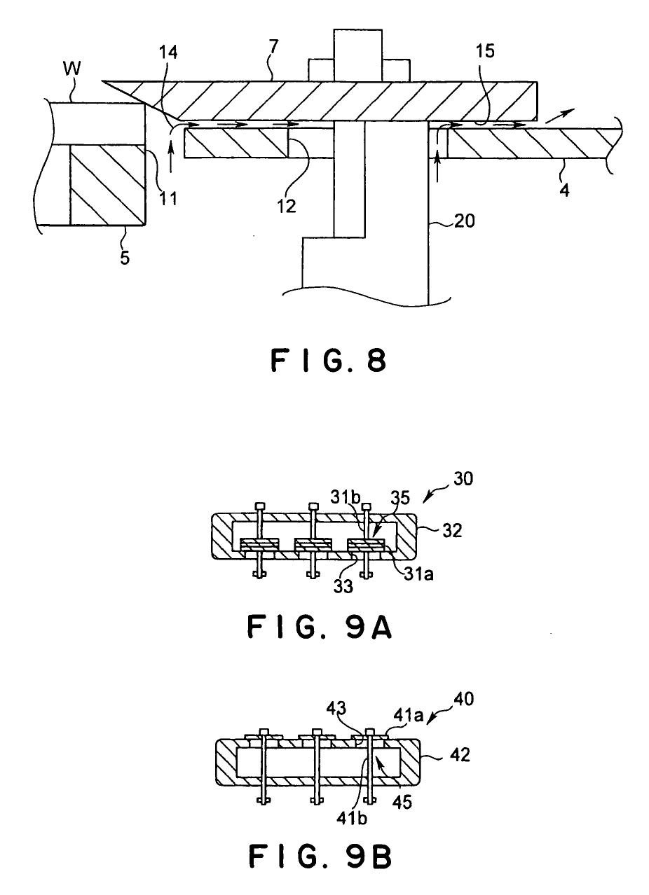

The transmission window 24 and the reflector 17 are provided inside the backside space 23 which is surrounded by aforementioned shield base 3. Further, at the base of the reflector 17, a purge gas introducing passage 37 is provided being connected at one end to a purge gas feeding device 59 and being communicated at the other end with the backside space 23. Through this purge gas introducing passage 37, a purge gas composed of inert gas that is nonreactive to a processing gas, such as Ar, nitrogen gas, for example, is supplied from the purge gas feeding device 59 into the backside space 23 in a regular process of film formation. In this case, as shown by the arrows in FIG. 6 and FIG. 8, a enlarged drawing of a periphery of the clamp ring 7, a purge gas supplied into the backside space 23 form a flow by flowing to the gap 11 defined between the pedestal 5 and the attachment 4 and at the same time flowing to the lower surface of the clamp ring 7 from the hole portions 12 to flow into the processing space 10 by way of a first flow path 15 and a second flow path 14 between the clamp ring 7 and the attachment 4. By forming the purge gas flow in this way, a processing gas is prevented from leaking and reaching to the rim part and backside surface of a wafer and into the backside space 23 to cause excess film depositing effects.

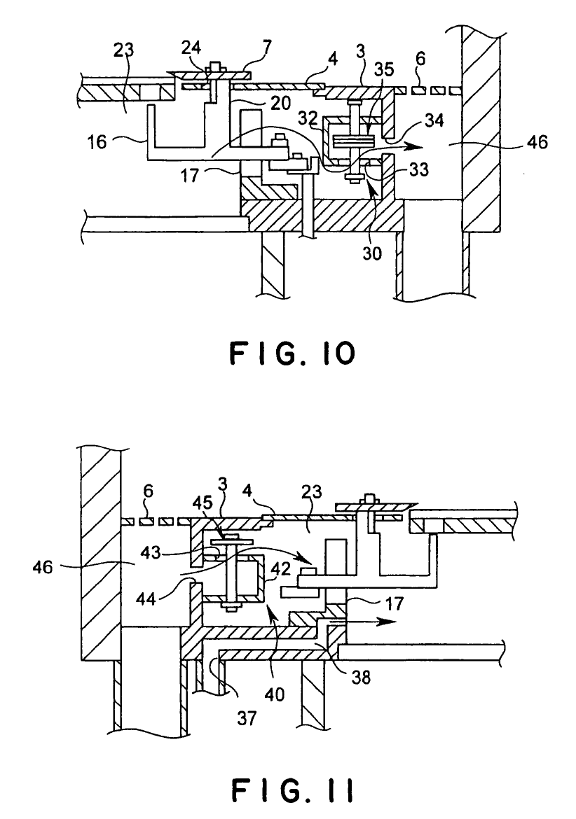

On the inward side of a sidewall of said shield base 3, a gas discharge mechanism 30 and a gas introducing mechanism 40 are provided. FIG. 9A is a longitudinal sectional view of the gas discharge mechanism 30 and FIG. 9B is a longitudinal sectional view of the gas introducing mechanism 40. The gas discharge mechanism 30 comprises: an opening 34 provided on the sidewall of the shield base 3; a valve body 32 which defines a chamber inside the shield base 3, said chamber communicating with the exhaust space 46 through said opening 34; discharge holes 33 provided at three points in the bottom of said valve body 32; and a valves 35 bearing valve elements 31a and shafts 31b and being inserted into said discharge holes 33 respectively, said valve elements 31a being larger than said discharge holes 33 in diameter. As shown in FIG. 6 and FIG. 7, the valves 35 are utilized to prevent a processing gas from leaking into the backside space 23 by sealing the discharge holes 33, normally, with the valve elements 31a by taking advantage of weight of the valves 35 themselves. However, as for a case that the processing space 10 is depressurized by a exhaust device 58, to be hereinafter described, through the exhaust space 46, when the pressure in the exhaust space 46 depressurized together with the processing space 10 becomes lower than the pressure in the backside space 23, the pressure differential applies an upward force on the valve elements 31a. Then if the pressure differential reaches predetermined or greater values, the valves 35 are moved up to open the discharge holes 33, and consequently a purge gas inside the backside space 23 is discharged into the exhaust space 46, as shown in FIG. 10. With regard to the valves 35 of this type which functions by a balance between forces generated from a pressure differential and the valve's own weight, the pressure differential for the valves 35 to be operated can be controlled by adjusting weight of the valve elements 31a corresponding to dimensions of the discharge holes 33.

At this occasion, the valves 35 are operated preferably before the pressure differential between the processing space 10 and the backside space 23 reaches a value to lift up the clamp ring 7. In this fashion, problems such as flip-flop of the clamp ring 7 can be completely prevented, when the processing space 10 is rapidly depressurized, by a purge gas discharged into the exhaust space 46 before the pressure differential between the processing space 10 and the backside space 23 reaches a value to lift up the clamp ring 7.

Also, in order to completely prevent a processing gas from leaking to the rim part and the backside surface of a wafer W at film formation, the valves 35 are preferably arranged not to operate by general pressure loss as a result of an flow of a purge gas into the processing space 10 through aforementioned first flow path 15 and second flow path 14 at film formation. If the valves 35 operate at the pressure differential at such level, an flow of sufficient amount of purge gas from the backside space 23 into the processing space 10 would be difficult at film formation, and also a processing gas would frequently escape into the backside space 23 to cause an increase of problems such as developed particles due to the unexpected film formation on the rim part and the backside surface of a wafer W.

Meanwhile, the gas introducing mechanism 40 comprises: an opening 44 provided on the sidewall of the shield base 3; a valve body 42 which defines a chamber inside the shield base 3, said chamber communicating with the exhaust space 46 through said opening 44; introducing holes 43 provided at three points on a ceiling wall of said valve body 42; and a valves 45 bearing valve elements 41a and shafts 41b and being inserted into said introducing holes 43 respectively, said valve elements 41a being larger than said introducing holes 43 in diameter. As shown in FIG. 6 and FIG. 7, these valves 45 are utilized to prevent a processing gas from leaking into the backside space 23 by sealing the introducing holes 43, normally, with the valve elements 41a by taking advantage of weight of the valves 45 themselves. However, when the pressure in the exhaust space 46 becomes higher than the pressure in the backside space 23, the pressure differential applies an upward force on the valve elements 41a which are moved up and open the introducing holes 43 when the pressure differential reaches predetermined or greater values, and consequently an atmosphere inside the exhaust space 46 is induced into the backside space 23, as shown in FIG. 11. The pressure differential for the valves 45 to be operated can be controlled by adjusting weight of the valve elements 41a corresponding to dimensions of the introducing holes 43.

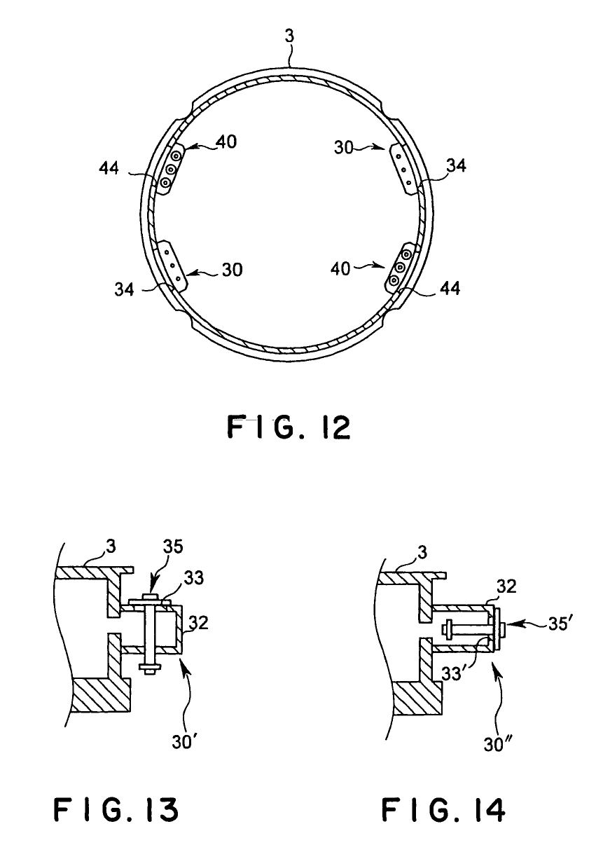

FIG. 12 is a cross-sectional view of FIG. 6, taken along line A-A, and shows an arrangement of the gas discharge mechanism 30 and the gas introducing mechanism 40 at the shield base 3. As shown, the gas discharge mechanism 30 and the gas introducing mechanism 40 as a pair are adjacently located at one side of the shield base 3, and also the gas discharge mechanism 30 and gas introducing mechanism 40 as another pair are located at the opposed side of the shield base 3 in the present embodiment. The arrangement in this way can prevent a pressure differential between the pressure in the chamber 1 and the pressure in the backside space 23 developed by operations of the gas discharge mechanism 30 and the gas introducing mechanism 40.

An exhaust device 58 is connected to the exhaust space 46 through vents 36 provided at four corners in the bottom of the chamber 1. The exhaust device 58 comprises a valve, not shown, for controlling air volume displacement from the exhaust device 58 so that a degree of vacuum in the processing space 10 can be maintained at a predetermined degree by exhausting the processing space 10 through the exhaust space 46. Further, the baffle plate 6 with numbers of hole portions provided between the exhaust space 46 and the processing space 10 helps the processing space 10 to be depressurized more slowly than the exhaust space 46 when the processing space 10 is depressurized in this way.

At the ceiling part of the chamber 1, a showerhead 50 is provided for introducing a processing gas etc. This showerhead 50 bears a shower base 51 formed to fit in the lid 2, and a gas introducing opening 55 is provided at the upper center of this shower base 51. Moreover, two tiered diffusion plates 52 and 53 are provided below this gas introducing opening 55, and a shower plate 54 is provided below these diffusion plates 52 and 53. To the gas introducing opening 55, a gas supply mechanism 60 is connected for supplying a processing gas etc. into the processing space 10 inside the chamber 1.

The gas supply mechanism 60 includes a ClF₃ gas source 61, an N₂ gas source 62, a WF₆ gas source 63, an Ar gas source 64, a SiH₄ gas source 65 and a H₂ gas source 66. To the ClF₃ gas source 61, a gas line 67 is connected, and a massflow controller 81 and open-close valves 74 and 88 are installed in this gas line 67, said open-close valves 74 and 88 being located in front and back of said massflow controller 81 respectively. To the N₂ gas source 62, a gas line 68 is connected, and a massflow controller 82 and open-close valves 75 and 89 are installed in this gas line 69, said open-close valves 75 and 89 being located in front and back of said massflow controller 82 respectively. To the WF₆ gas source 63, a gas line 69 is connected, and a branch line 70 branches from on the way of this gas line 69. In this gas line 69, a massflow controller 83 and open-close valves 76 and 90 are installed, said open-close valves 76 and 90 being located in front and back of said massflow controller 83 respectively, and in the branch line 70, a massflow controller 84 and open-close valves 77 and 91 are installed, said open-close valves 77 and 91 being located in front and back of said massflow controller 84 respectively. This branch line 70 is utilized in a nucleation process, to be hereinafter described, to control the flow rate more accurately. To the Ar gas source 64, a gas line 71 is connected, and a massflow controller 85 and open-close valves 78 and 92 are installed in this gas line 71, said open-close valves 78 and 92 being located in front and back of said massflow controller 85 respectively. At this point, said gas line 69 and said branch line 70 are connected to merge onto this gas line 71, and the Ar gas functions as carrier gas for the WF₆ gas. To the SiH₄ gas source 65, a gas line 72 is connected, and a massflow controller 86 and open-close valves 79 and 93 are installed in this gas line 72, said open-close valves 79 and 93 being located in front and back of said massflow controller 86 respectively. To the H₂ gas source 66, a gas line 73 is connected, and a massflow controller 87 and open-close valves 80 and 94 are installed in this gas line 73, said open-close valves 80 and 94 being located in front and back of said massflow controller 87 respectively. To a gas line 95, those gas lines 67, 68, 71, 72 and 73 are connected, and this gas line 95 is connected to the gas introducing opening 55.

Hereinafter, examples of operations to form a W film on the front surface of a wafer W by the CVD film formation apparatus 100 which is structured as above described will be explained. Table 1 shows changes of the pressure in a processing space and flow rate of a purge gas measured at step 1 through step 10 of a process from loading of a wafer W to unloading of the wafer W, as in this example.

TABLE 1

| | Pressure in | |
|---|---|---|
| | Processing Space | Purge Gas Flow Rate |
| Step | (Pa) | (× 10⁻² L/min.) |
| 1 | 0 | 0 |
| 2 | 500 | 50 |
| 3 | 500 | 50 |
| 4 | 500 | 50 |
| 5 | 0 | 50 |
| 6 | 10666 | 100 |
| 7 | 10666 | 100 |
| 8 | 10666 | 100 |
| 9 | 0 | 100 |
| 10 | 0 | 0 |

Firstly, a gate valve, not shown, provided on the side wall of the chamber 1 is opened and a wafer W is loaded into the chamber 1 by a transfer arm, and after the wafer W is received by the lift pins 16 which are moved up to be projected for a predetermined length from the pedestal 5, the transfer arm is retreated from the chamber 1, and the gate valve is closed.

In this state of things, supplying any gas neither from the gas supply mechanism 60 nor from the purge gas feeding device 59, an exhaust valve of the exhaust device 58 is fully opened for the chamber 1 to be rapidly depressurized, and after the chamber 1 reaches a high vacuum state inside with the ultimate pressure of 100 mTorr, the lift pins 16 and the clamp ring 7 are moved down, and then the lift pins 16 are the pedestal 5 for the wafer W to be mounted on the pedestal 5 and at the same time the lift pins 16 are moved down to a position for the clamp ring 7 to directly contact and support the wafer W (STEP 1).

In this way, the wafer W is mounted and then held by the clamp ring 7 with the chamber 1 in a high vacuum state so as to prevent the wafer W from slipping over the pedestal 5. Further, the wafer W is heated to reach a predetermined temperature by lighting the lamps 26 inside the heat chamber 25 to release thermal radiation with the rotating table 27 being rotated by the rotating motor 29.

Then, in order to form a nucleation film on the front surface of the wafer W mounted on the pedestal 5 and held by the clamp ring 7, valve travel of the exhaust valve at the exhaust device 58 narrows down, processing gas or purge gas is started supplying from the N₂ gas source 62, Ar gas source 64, SiH₄ gas source 65 and H₂ gas source 66 of the gas supply mechanism 60 and from the purge gas feeding device 59 respectively at predetermined flow rates, and a pressure inside the processing space 10 is set at 500 Pa (STEP 2). After that, with the flow rate of each gas maintained, supply of WF₆ gas is started with less flow rate than the flow rate for a main film formation process, to be hereinafter described, from the WF₆ gas source 63 through the branch line 70 with the flow rate strictly controlled by the high-precision massflow controller (STEP 3). Under these conditions, a nucleation film is formed on the wafer W by SiH₄ reduction reaction as shown in a formula (1) below developed for a predetermined time period (STEP 4). Meanwhile, the pressure inside the processing space 10 at said STEP 3 and STEP 4 is maintained at 500 Pa.

2WF₆+3SiH₄→2W+3SiF₄+6H₂ (1)

After that, the supply of WF₆ gas and SiH₄ gas is ceased, and with supplying amounts of the other gases maintained, the processing space 10 is rapidly depressurized inside by fully opening the exhaust valve at the exhaust device 58, and thus the processing space 10 is purged of the processing gas remained after the nucleation film formation (STEP 5).

Next, a main film formation process is initiated, in which a W film is formed on the front surface of a wafer W with a nucleation film formed thereon as above-described. Firstly, while valve travel of the exhaust valve at the exhaust device 58 narrows down, each flow rate of Ar gas as a carrier gas, H₂ gas, N₂ gas and a purge gas is increased, and the pressure inside the processing space 10 is raised to 10666 Pa (STEP 6). Subsequently, while WF₆ gas for main depositing is started supplying from the WF₆ gas source 63 of the gas supply mechanism 60, Ar gas, H₂ gas and N₂ gas are decreased to fill the processing space 10 with a processing gas atmosphere for main deposition (STEP 7). Under these conditions, W film formation by H₂ reduction reaction as shown in a formula (2) below is performed for a predetermined time period (STEP 8). Meanwhile, the flow rate of the purge gas and the pressure inside the processing space 10 at said STEP 7 and said STEP 8 are maintained as in STEP 7.

WF₆+3H₂→W+6HF (2)

After completing the main film formation, as a preparation for unloading the wafer W, the supply of WF₆ gas and SiH₄ is ceased, and the chamber 1 is rapidly depressurized inside by fully opening the exhaust valve at the exhaust device 58 with the supply of Ar gas, H₂ gas, N₂ gas and a purge gas maintained, and thus the processing space 10 is purged of the processing gas remained after the main film formation (STEP 9). After that, with all the gas supply stopped, depressurization inside the chamber 1 is continued to reach a high vacuum state (STEP 10).

In this high vacuum state, the lift pins 16 and the clamp ring 7 are moved upward to release the wafer W from holding by the clamp ring 7, and the lift pins 16 are moved up to reach a position to be projected for a predetermined length from the pedestal 5 so that the transfer arm can receive the wafer W. In this way, the wafer W is released and lifted by the lift pins 16 with the chamber 1 in a high vacuum state so as to prevent the wafer W from slipping over the pedestal 5, as in STEP 1.

After that, a purge gas, Ar gas, etc. are introduced into the chamber 1, and the gate valve is opened for the transfer arm to enter the chamber 1, and then the wafer W on the lift pins 16 are received by the transfer arm, and thus the wafer is unloaded by retreating the transfer arm from the chamber 1 and the film formation operation is completed. Further, after unloading the wafer W, cleaning inside the chamber 1 is performed as necessary by supplying ClF₃ gas into the chamber 1 etc.

In a process as described above, especially at said STEP 5, said STEP 9 and said STEP 10, pressures inside the processing space 10 and the exhaust space 46 are rapidly decreased since the valve at the exhaust device 58 are fully opened for rapid depressurization. In this occasion, the clamp ring 7 would become flip-flop by an large pressure differential developed between the backside space 23 and the processing space 10 in conventional apparatuses. However, in the present embodiment, problems such as flip-flop of clamp ring 7 can be avoided due to the gas discharge mechanism 30 discharging a purge gas from the backside space 23 into the exhaust space 46 before the pressure differential reaches a level to effect on the clamp ring 7. Moreover, since the gas discharge mechanism 30 is not made to operate by pressure loss generally caused by an flow of a purge gas into the processing space 10 at film formation, a purge gas is not released at said STEP 2 through STEP 4 in the nucleation process and said STEP 6 through STEP 8 in the main film formation process, and a processing gas is adequately prevented from entering the rim part and the backside surface of a wafer W by a purge gas.

Furthermore, in a case of malfunction or breakdown of the conventional apparatuses, pressures inside the processing space 10 and the exhaust space 46 would become extremely higher than a pressure inside the backside space 23 to cause possible damages to members constructing the CVD film formation apparatus 100 by the pressure differential. However, in the present embodiment, the pressure differential can be decreased by the gas introducing mechanism 40 introducing the atmosphere inside the exhaust space 46 into the backside space 23, and therefore damages to the members thus caused by the pressure differential can be prevented.

Next, examples of designs for the valves 35 in said gas discharge mechanism 30 will be explained. In this instance, a case that the valves 35 are structured based on actual common data is described.

The clamp ring 7 holds a wafer W on the pedestal 5 by the own weight of the clamp ring 7 and a force generated by three springs that connect the clamp ring 7 and three lift pins 16 respectively. The actual weight of the clamp ring 7 is 0.9N, the force of said springs is 15N in total and a dimension A of the clamp ring 7 equals 0.0185 m², and the clamp ring 7 holds a wafer W by a force of 0.9N+15N=15.9N. Therefore, when a greater force than this 15.9N is generated by the pressure differential between the processing space 10 and the backside space 23 and actuated in the upward direction of the clamp ring 7, the clamp ring 7 may begin to become flip-flop. This fact permits the pressure differential ΔP₁ between the processing space 10 and the backside space 23 to cause flip-flop of the clamp ring 7 in this actual demonstration to be sought by:

ΔP₁=15.9/0.0185=859.5 Pa.

Based on the actual data, the pressure loss ΔP₂ caused by the flow of a purge gas from the backside space 23 into the processing space 10 at a film formation is also calculated: ΔP₂≈113 Pa. Therefore, when a purge gas is discharged under the condition that the pressure differential between the exhaust space 46 and the backside space 23 is ΔP₂ or less, the purge gas cannot sufficiently be provided at the film formation.

As described above, the pressure differential P to operate the valves 35 in this demonstration is preferably ranged:

ΔP₁<P<Δ₂, i.e. 113 Pa<P<859.5 Pa,

thereby a processing gas is effectively prevented from escaping to the rim part and the backside surface of a wafer W by a purge gas at a film formation, and also flip-flop of the clamp ring 7 caused at a rapid depressurization is prevented.

To operate by a pressure differential at this preferable range, the valve 35 are structured. In this instance, an outside diameter of the valve elements 31a is set as 14 mm, thickness 1.5 mm in consideration of the space where the gas discharge mechanism 30 is located. The pressure differential for thus structure valve elements 31a to operate is calculated 143 Pa per piece, and consequently the pressure for the valve 35 to operate can be within the aforementioned preferable range of 429 Pa by using three valve elements 31a for one valve 35. Although one valve element 31a with a thickness of 4.5 mm may be applied instead, three valve elements 31a with a thickness of 1.5 mm each is chosen for easier adjustments in this case. By applying thus structured valves 35 to the gas discharge mechanism 30, a processing gas can be prevented from escaping into the backside space 23 by a purge gas at a film formation, and also flip-flop of the clamp ring 7 can be prevented by adequately discharging a purge gas from said backside space 23 at depressurization inside the processing space 10. Meanwhile, these examples concern a design of the valve 35 structured based on the actual common data, and therefore a preferable range of the pressure differential and structure of the valve 35 are not limited by the above examples.

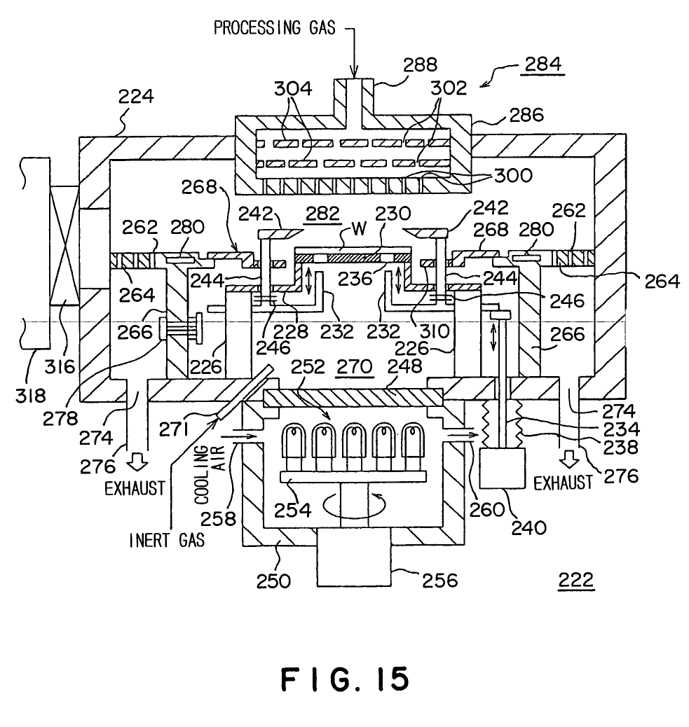

Meanwhile, the present invention is not limited by the above embodiment, but may be variously modified. For instance, although the gas discharge mechanism 30 and the gas introducing mechanism 40 are both formed to be inwardly projected inside the shield base 3 according to the above embodiment, both can be formed to be outwardly projected outside the shield base 3 as a gas discharge mechanism 30′ shown in FIG. 13. In this case, the valve can be horizontally provided as shown in a gas discharge mechanism 30″ in FIG. 14. However, since valves 35′ which are horizontally provided cannot seal discharge holes 33′ by the weight of the valves 35′ themselves, the valves 35′ need to be structured for pressing the discharge holes 33′ by springs etc. Further, in the above embodiment, the gas discharge mechanism 30 and the gas introducing mechanism are 40 both structured to have three pairs of the discharge holes 33 and 43 and the valves 35 and 45 respectively, but the number is not limited. Moreover, the number of the gas discharge mechanism 30 and the gas introducing mechanism 40 and the location thereof can also be changed.

Furthermore, the present invention is not limited by a W film formation by CVD discussed in the above embodiment. For instance, the other materials such as Al, WSi, Ti and TiN can be applied to the CVD film formation, and also gas processing other than the CVD can be applied. Moreover, substrates-to-be-processed are not limited by a wafer but other substrates can be applied.

As explained above, according to the present invention, in a case that a pressure in said space becomes higher for predetermined values than a pressure outside said space within processing container, by comprising a gas discharge mechanism which discharges said purge gas from said space, a processing gas can be prevented from entering said space by said purge gas when said substrate is processed, and also said purge gas can be discharged from said space by said gas discharge mechanism when said processing container is depressurized, and thus no large pressure differential is produced between inside and outside said space within said processing container, and therefore problems such as flip-flop of said substrate supporting members can be prevented. As a result, said processing space can be rapidly depressurized after a film formation process etc. and throughput can be enhanced by reducing the processing time.

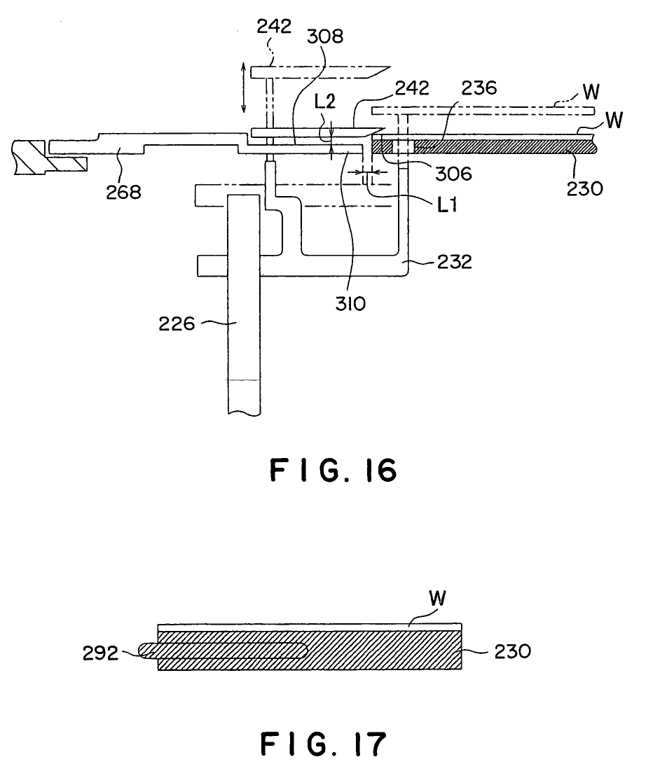

Next, the other embodiment of the present invention will be explained in reference to FIG. 15 to FIG. 20. FIG. 15 is a cross-sectional view of an example of a processing apparatus according to the present invention, and FIG. 16 is an enlarged cross-sectional view showing a rim part of a susceptor as a pedestal which also functions as a acceptance heating element shown in FIG. 15. Since the following embodiment concern a thermal processing, hereinafter “processing apparatus” will be referred to as “thermal processing apparatus.” In the present embodiment, a single-wafer film formation apparatus with high-speed heating by heating lamps exemplifies the thermal processing apparatus.

The film formation apparatus 222 has a cylindrical or box-shaped processing container 224 composed of aluminum for example, and inside the processing container 224, a susceptor 230 is provided on a ring-shaped reflecting support 226 risen from the base of the container, said susceptor 230 also functioning as a pedestal for mounting a semiconductor wafer W as an object through three holding members 228, said holding members 228 having L-shaped cross-sectional surface and being discreetly located circumferentially onto said susceptor 230 functioning also as a pedestal for example. A diameter of the susceptor 230 is arranged as approximately the same as a wafer W to be processed. Further, the holding members 228 are composed of a material which transmits thermal radiation, mainly infrared wavelengths (thermal radiation), from heating lamps 252, to be hereinafter described, such as quartz (silicon dioxide). The reflecting support 226 is mirror-finished inside to reflect thermal radiation for the susceptor 230 to be exposed.

Below this susceptor 230, a plurality (e.g. 3 pieces) of L-shaped lifter pins 232 are provided, and lifter pin secure rings, not shown, connect each lifter pin 232 to each other. Said lifter pins 232 are inserted in lifter pin holes 236 as relief holes by moving the lifter pin secure rings up and down by a pushup stick 234 so that a wafer W can be lifted from the susceptor 230 or supported by the susceptor 230, said lifter pin holes 236 being provided by being pierced by said lifter pins 232 through susceptor 230, said pushup stick 234 being provided by piercing through the base of the container.

The lower end of said pushup stick 234 is joined to an actuator 240 through elastic bellows 238 to keep airtightness inside the processing container 224. At the rim part of said susceptor 230, a ring-shaped ceramic clamp ring 242 is provided as a secure means for example to secure a wafer W on the side of the susceptor 230 by pressing the rim part of the wafer W, and this clamp ring 242 is joined to said lifter pins 232 by way of a ring arm 244 to be moved up and down in one body, said ring arm 244 being made of quartz (silicon dioxide) and piercing with play through said holding members 228. At this point, coiled springs 246 are inserted on the ring arm 244 between the horizontal areas of the holding members 228 and the lifter pins 232 to bias the clamp ring 242 etc. downward and ensure secure clamping of a wafer W. These lifter pins 232 and holding members 228 are also composed of heat-ray transmissive materials such as quartz (silicon dioxide).

Further, at an opening in the bottom of the processing container 224 directly underneath the susceptor 230, a transmission window 248 composed of heat-ray transmissive material such as silicon dioxide is installed airtight, and below the transmission window 248, a box-shaped heat chamber 250 is provided surrounding the transmission window 248. Inside the heat chamber 250, a plurality of heating lamps 252 as a heating means comprising halogen lamps etc. are installed on a rotating table 254 which also functions as a reflector, and this rotating table 254 can be rotated by a rotating motor 256 which is provided at the bottom of the heat chamber 250 via a rotating shaft. Consequently, thermal radiation released from the heating lamps 252 can transmit through the transmission window 248 and expose the lower surface of the susceptor 230 for heating, and thus heating a wafer W by the thermal conduction from the susceptor 230.

Numbers of said heating lamps 252 are located radially from the center. The heating lamps 252 located at the center part mainly heat the center part of the susceptor 230, and the heating lamps 252 located outside the center part mainly heat the parts from the center to the end part of the susceptor 230, and the heating lamps 252 located in the outmost position mainly heat the clamp ring 242.

On the sidewall of this heat chamber 250, a cool air introducing opening 258 for introducing cool air to cool down inside this heat chamber 250 and the transmission window 248 and a cool air discharge opening 260 for discharging the air are provided. Then at the bottom of the processing container 224, a gas nozzle 271 is provided by piercing the bottom of the processing container 224 to reach the inner side of a chamber 270 defined below the susceptor 230, and the gas nozzle 271 feeds inert gas (N₂, Ar, etc.) , such as flow-rate controlled Ar gas as a backside gas from an Ar gas source which retains Ar, not shown, into the chamber 270. Thus adhering of formed films on the inside surface of the transmission window 248 etc., which causes opaque to thermal radiation, by a processing gas entering this chamber 270 is prevented.

Further, in the outer circumferential side of the susceptor 230, a ring-shaped current plate 264 having numbers of current holes 262 is provided being sandwiched to be supported between a supporting column 266 and the inside wall of the processing container 224, said supporting column 266 being formed vertically annular. At the upper end on the side of the internal circumference of the supporting column 266, a ring-shaped attachment member 268 made of quartz (silicone dioxide) is provided by being supported by said internal circumferential end of the supporting column 266 in order to section inside the processing container 224 into upper and lower chambers to permit as less processing gas flowing into the chambers on the lower side of the susceptor 230 as possible. On the upper part of the column 266, a water-cooling jacket 280 is provided to cool down mainly the side of the current plate 264. At the base part below the current plate 264, a vent 274 is provided, and this vent 274 is connected to a discharge path 276 which is connected to a vacuum pump, not shown, so that a predetermined degree of vacuum (e.g. 0.5 Torr to 100 Torr) can be maintained by evacuating the processing container 224. In addition, a pressure relief valve 278 is provided on said supporting column 266 to prevent the inner side of the chamber 270 below the susceptor 230 from being in a state of extreme positive pressure.

Meanwhile, at the ceiling part of the processing container 224 opposed against said susceptor 230, a gas feed portion 284 is provided for introducing necessary gases such as a processing gas and a cleaning gas into a reaction chamber 282. More specifically, this gas feed portion (a showerhead) 284 has a showerhead structure and comprises a head body 286 formed in a shape of a cylindrical container by aluminum for example, the ceiling part of said head body 286 having a gas introducing port 288. This gas introducing port 288 is connected to a gas source, not shown, through a gas passage and a plurality of guiding branches so that N₂, H₂, WF₆, Ar, SiH₄, ClF₃, etc. can be supplied respectively from each gas source.

On the lower surface of the head body 286, opposed against the susceptor 230, a plurality of gas holes 300 are evenly located within the surface for releasing gas supplied into the head body 286, and thus gas can be released evenly over the surface of a wafer W. Further, inside the head body 286, two tiered diffusion plates 304 with a plurality of gas diffusion holes 302 are disposed for supplying gas on a wafer W more evenly.

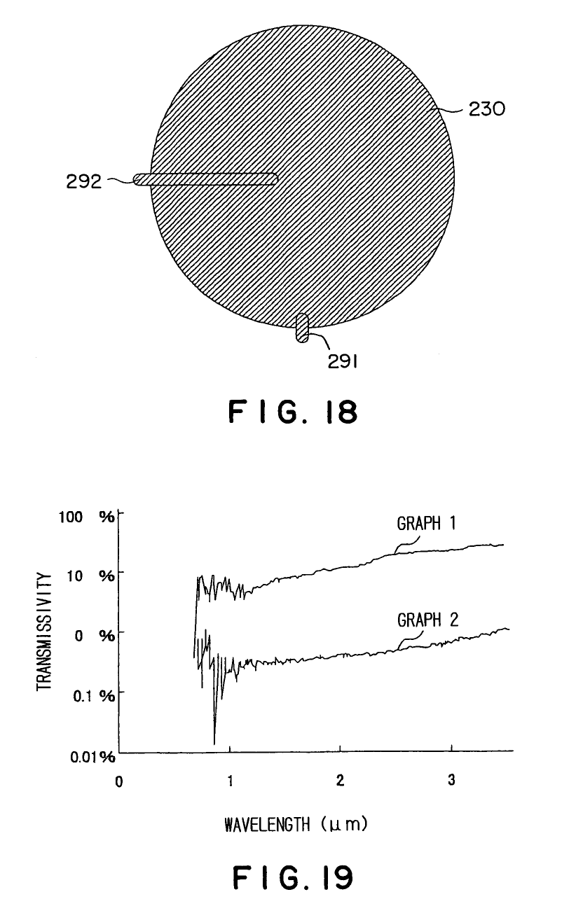

Hereinafter, the susceptor 230 according to the present embodiment is explained in more detail. The susceptor 230 contains a temperature sensor (TC) for a susceptor temperature control, said temperature sensor being a dissimilar member composed of a material which is different from the susceptor material. Due to the film formation apparatus 222 according to the present embodiment for handling a wafer W with a diameter of 300 mm, temperature control only by the temperature sensor at the edge part of the susceptor 230 is inadequate, so a second temperature sensor (TC) is inserted from the edge part of the susceptor 230 to a position closer to the center so that temperature control is performed by these two sensors. To be more precise, as shown in FIG. 17 and FIG. 18, a temperature sensor 291 is inserted into the susceptor 230 to a position of approximately 15 mm from the edge part and also a second temperature sensor 292 is inserted into the susceptor 230 to a position of approximately 120 mm from the edge part close to the center. For example, these temperature sensors 291 and 292 are composed of sheathed thermocouple. The sheath material shall be refractory metals such as hastelloy, inconel and pure nickel.

Since these temperature sensors 291 and 292 have low thermal radiation transmissivity, the transmittance differential becomes large in a case that said susceptor 230 is composed of a material with high thermal radiation transmissivity such as white-colored AlN-based ceramics as in the conventional cases. The differential of thermal radiation absorptance becomes large if the transmittance differential is large, which causes uneven temperature distribution within the susceptor 230.

Therefore, the susceptor 230 of the film formation apparatus 222 according to this embodiment is composed of black-colored AlN-based ceramics which has low thermal radiation transmissivity.

Generally, said AlN-based ceramics is used for acceptance heating elements such as a susceptor for its outstanding thermal conduction and mechanical characteristics. The color of the AlN-based ceramics changes depending on kind and amount of impurities and sintering aids. For instance, white or gray-colored AlN-based ceramics is fire-formed using high-purity AlN materials with fewer impurities of transition metals. Also, black-colored AlN-based ceramics is formed by including titanium, cobalt, etc. or AlON, carbon, etc. in AlN materials. Especially, inclusion of AlON is effective due to less color shading and excellence in mechanical characteristics.

FIG. 19 shows correlations between wavelengths of light transmitted through AlN-based ceramics and transmissivities of the wavelengths. The FIG. 19 is a logarithmic graph wherein the horizontal axis shows wavelength of light transmitted through AlN-based ceramics and the vertical axis shows transmissivity (indicated in logarithm). Graph 1 is for white-colored AlN-based ceramics and Graph 2 is for black-colored AlN-based ceramics. Both the white-colored and the black-colored AlN-based ceramics have a thickness of 3.5 mm.

As shown in FIG. 19, at the wavelength of approximately 1 μm or longer, the transmissivity of the black-colored becomes approximately 1/40 of the transmissivity of the white-colored. Wavelength regarded as thermal radiation is infrared light (0.78 μm to 1000 μm), and the black-colored has a decrease especially in transmissivity of this thermal radiation. In a case that halogen lamps are used for heating lamps 252 as a heat source and the halogen lamps can provide wavelength of 0.6 μm to 3 μm which is regarded as thermal radiation, the black-colored AlN-based ceramics can have a decrease in transmissivity of this thermal radiation to approximately 1/40.

Since the susceptor 230 according to the present embodiment is composed of this type of black-colored AlN-based ceramics with low thermal radiation transmissivity, the thermal radiation transmittance differential between the susceptor 230 and the contained temperature sensors 291, 292 can be decreased, and also the temperature differential within the susceptor 230 can be decreased. Therefore, evenness of the temperature distribution can be improved.

Meanwhile, because the color of AlN-based ceramics composing the susceptor 230 changes depending on kind and amount of impurities and sintering aids, AlN-based ceramics with the thermal radiation transmissivity equal to or lower than the thermal radiation transmissivity of dissimilar materials inserted in the susceptor 230 can decrease impacts, caused by containing of dissimilar members, on the temperature distribution of the susceptor 230, and thus evenness of the temperature distribution can be improved.

A film formation that is processed based on thus structured film formation apparatus 222 will be hereinafter explained. In the following, a case that a tungsten film is formed a surface by CVD is exemplified, wherein a TiN barrier metal layer has been already formed on a surface of Si wafer by sputtering apparatus. Firstly, a semiconductor wafer W with a TiN barrier metal layer accommodated inside a load lock chamber 318 is loaded by a transfer arm, not shown, into the processing container 224 through a gate valve 316, said processing container 224 being vacuumed in advance, and the wafer W is transferred to the side of liter pins 232 by pushing up the lifter pins 232. Then, the wafer W is mounted on the susceptor 230 by the lifter pins 232 moved down by the pushup stick 234 moved down by operating the actuator 240, and also, by further moving down the pushup stick 234, the inner end surface part of ring-shaped clamp ring 242 contacts the rim part of the wafer W for the wafer W to be pressed down and secured. Then, after the processing container 224 is evacuated to reach the degree of the base pressure, the heating lamps 252 inside the heat chamber 250 are lighted and rotated to release thermal radiation.

The thermal radiation released from the heating lamps 252 transmits through the transmission window 248, and thus the backside surface of the susceptor 230 is exposed and heated. For the heating, the output of the heating lamps 252 is adjusted based on the temperature measured by the temperature sensors 291 and 292. At this occasion, due to the susceptor 230 composed of black-colored AlN-based ceramics with low transmissivity of thermal radiation from the heating lamps 252, differential of thermal radiation transmissivities between the susceptor 230 and the contained temperature sensors 291, 292 is decreased and also the temperature differential within the susceptor 230 is decreased, and thus temperature distribution of the susceptor 230 is improved. Consequently, evenness of the temperature distribution of the wafer W on the susceptor 230 is also improved because the heat is transmitted by heat conduction from the susceptor 230 structured in this way, and a film can be evenly formed.

Then, when the semiconductor wafer W reaches a temperature for processing, N₂ gas as a carrier gas, WF₆ gas as a processing gas and H₂ gas and Ar gas as a reduction gas are supplied from respective gas sources, not shown, into the reaction chamber 282 inside the processing container 224. Meanwhile, helium gas can substitute the N₂ gas or Ar gas. The mixed gas supplied in this way develops predetermined chemical reactions, and a tungsten film is formed on the TiN film. This film forming processing is continued until a predetermined thickness of the film is achieved.

During the film formation processed in this way, a processing gas is prevented from escaping into the chamber 270 below the susceptor 230 by supplying N₂ gas as a backside gas from the N₂ gas source for this chamber 270 to be arranged to slightly have positive pressure in comparison with the reaction chamber 282 above. N₂ gas can be substituted by inert gas such as Ar, or by H₂ gas. Further, as shown in FIG. 16, the backside gas supplied into the chamber 270 below the susceptor 230 flows from the width L1 as an entrance and through a gas purge passage 308 and flows out from the outer end portion of the clamp ring 242 into the reaction chamber 282 as shown by the arrows, said width L1 being formed between the outer end surface of the susceptor 230 and the inner end surface of the attachment member 268 and having width of 0.5 to 10 mm for example, 1 to 5 mm preferably. In this way, by clamping state of the clamp ring 242, the gas purge passage 308 with a small width L2, 0.5 to 10 mm for example, 1 to 5 mm preferably, is formed between the lower surface of the clamp ring 242 and the upper surface of a shoulder portion 310 on the internal circumferential side of the attachment member 268 in order to completely purge a processing gas entering below.

In this way, the differential of thermal radiation transmissivities between the susceptor 230 and the contained temperature sensors 291, 292 can be decreased and also the temperature differential within the susceptor 230 can be decreased, due to the susceptor 230 composed of black-colored AlN-based ceramics with low transmissivity of the thermal radiation from the heating lamps 252 according to the present embodiment. Consequently, evenness of the temperature distribution of the susceptor 230 is improved. Therefore, evenness of the temperature distribution of a semiconductor wafer W on the susceptor 230 can be improved, and evenness of thickness of a film formed on a semiconductor wafer W can be improved. In this case, the thermal radiation transmissivity differential between the susceptor 230 and the contained dissimilar members such as temperature sensor can be further decreased and also the temperature differential within the susceptor 230 can be further decreased, by the susceptor 230 composed of a material (including the aforementioned black-colored AlN-based ceramics) with a thermal radiation transmissivity equal to or lower than the thermal radiation transmissivities of dissimilar members such as temperature sensors. Consequently, evenness of the temperature distribution of the susceptor 230 is further improved. Therefore, evenness of the temperature distribution of a semiconductor wafer W on the susceptor 230 can be further improved, and evenness of thickness of a film formed on a semiconductor wafer W can be further improved. For instance, since the color black of AlN-based ceramics changes depending on kind and amount of impurities such as AlON and sintering aids and thus the thermal radiation transmissivity changes, the susceptor 230 may be composed of a AlN-based ceramics with adequate blackness to have a thermal radiation transmissivity equal to or lower than the thermal radiation transmissivities of dissimilar members.

Meanwhile, the present embodiment is described with reference to the susceptor 230 being inserted by the temperature sensors (TC) 291 and 292 as dissimilar members. However, the invention is not limited by the above embodiment, but may be applied to a susceptor being inserted by the other dissimilar members. Consequently, evenness of the temperature distribution of the susceptor 230 is improved. Therefore, evenness of the temperature distribution of a semiconductor wafer W on the susceptor 230 can be also improved, and evenness of thickness of a film formed on a semiconductor wafer W can be also improved.

Also, certain temperature sensors contained by the susceptor 230 might have different thermal radiation transmissivities at each part of the temperature sensors themselves. In this case, if the susceptor 230 is composed of white-colored AlN-based ceramics with high thermal radiation transmissivity as in a conventional way, the temperature distribution becomes uneven even within the part where the temperature sensor is contained. Consequently, the temperature distributions of the surface of a semiconductor wafer W heated through the susceptor 230 and of the part where the temperature sensor is contained become uneven, and the film thickness becomes uneven at film formation processing.

However, evenness of the temperature distribution of the part of this temperature sensor can be improved by the susceptor 230 composed by black-colored AlN-based ceramics with low thermal radiation transmissivity as in this embodiment.

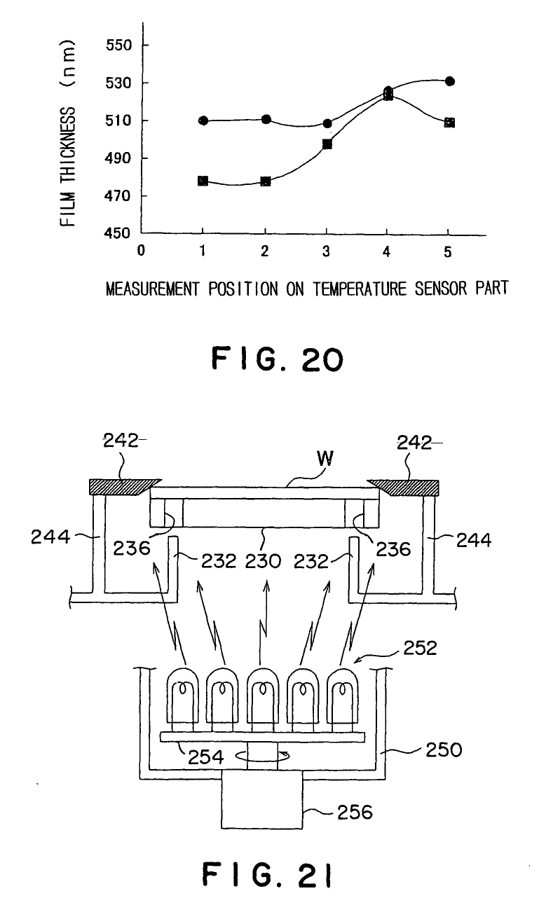

FIG. 20 shows a result of an experiment, wherein a film formation is processed on a semiconductor wafer and the film thickness formed on a part of a temperature sensor is measured. Using processing gases WF₆, Ar, SiH₄, H₂, N₂, etc., a nucleus is formed under the substantial pressure of 500 Pa, and a tungsten film is formed under the substantial pressure of 10666 Pa, and then the points of measurement are gauged on a film with thickness formed on a semiconductor wafer W from the center side to the edge side (1 to 5) and resistance values of the points are measured, and based on each resistance value, thickness is calculated. In this case, a semiconductor wafer W is controlled to maintain 445° C.

Also in FIG. 20, the horizontal axis shows each point and the vertical axis shows thickness value of films at the points. Each point 1 to 5 is measured 4 mm, 15 mm, 34 mm, 60 mm and 95 mm from the center of a semiconductor wafer W respectively. Also, in the same figure, the graph with black squares shows each film thickness value in which a film formation is processed with a susceptor composed of white-colored AlN-based ceramics with high thermal radiation transmissivity as in a conventional apparatus, and the graph with black circles shows each film thickness value in which a film formation is processed with a susceptor composed of black-colored AlN-based ceramics with low thermal radiation transmissivity according to the present embodiment.

The result of the experiment in this FIG. 20 indicates that, in the case of the susceptor with low thermal radiation transmissivity according to the present embodiment, as shown in the graph with black circles, the differential between the maximum and the minimum thickness values is small and evenness of the film thickness on the temperature sensor part is improved, compared to the susceptor with high thermal radiation transmissivity as shown in the graph with black squares.

In this way, by the susceptor 230 composed of black-colored AlN-based ceramics with low thermal radiation transmissivity, evenness of the temperature distribution of the temperature sensor part within the susceptor 230 can be also improved. Consequently, evenness of thickness of a film formed on a semiconductor wafer W at the part being inserted by the temperature sensor can still be improved.

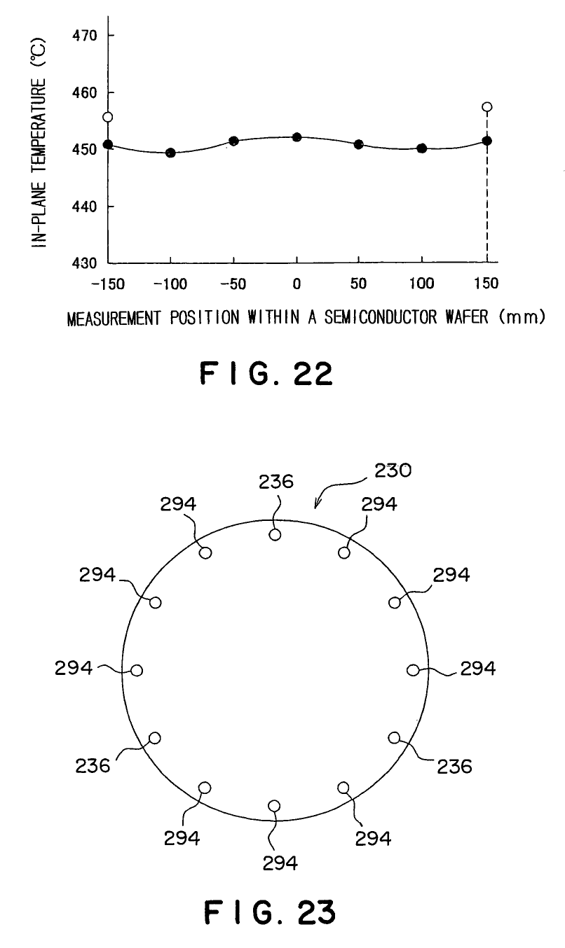

Next, another embodiment of a thermal processing apparatus according to the present invention will be explained with reference to FIG. 21 and FIG. 22. Meanwhile, as the above-described embodiment, a single-wafer film formation apparatus with high-speed heating by heating lamps exemplifies the thermal processing apparatus also in the present embodiment. Since a cross-sectional view of the whole structure of the film formation apparatus and an enlarged cross-sectional view showing the rim part of the susceptor are the same as FIG. 15 and FIG. 16 respectively, detailed explanations will be omitted. FIG. 21 is an enlarged diagrammatic sectional view of the susceptor 230 and the rim part of the clamp ring 242.

In the present embodiment, the susceptor 230 is composed of white-colored AlN-based ceramics and also the clamp ring 242 as a object pressing member is composed of black-colored AlN-based ceramics, as shown in FIG. 21.

In this case, if said susceptor 230 and clamp ring 242 are composed of the same white-colored AlN-based ceramics, temperature of the clamp ring 242 becomes lower than the temperature of the susceptor 230 in the same way shown in FIG. 5 even by receiving thermal radiation from the heating lamps 252 of the same a heat source, because the clamp ring 242 is ring-shaped and narrower in dimension with high heat escape level. Furthermore, since the clamp ring 242 has contact only with the rim part of a semiconductor wafer W, the temperature of the rim part of a semiconductor wafer W becomes lower than the temperature of the center part and its peripheral part (−100 mm to 100 mm) due to the clamp ring 242 absorbing heat from the rim part (100 mm to 150 mm, −100 mm to −150 mm) of the semiconductor wafer W. Consequently, the temperature distribution is considered to be uneven.

Given this factor, in the present embodiment, the clamp ring 242 is composed of black-colored AlN-based ceramics with lower thermal radiation transmissivity than the susceptor 230. Consequently, the temperature of the clamp ring 242 becomes higher than the temperature of the susceptor 230 even by receiving thermal radiation from the heating lamps 252 as the same heat source, and thus unevenness of the temperature distribution due to the clamp ring 242 absorbing heat from the rim part of a semiconductor wafer W can be prevented.

FIG. 22 shows a result of an experiment, wherein the clamp ring 242 is composed of black-colored AlN-based ceramics with lower thermal radiation transmissivity than the susceptor 230, a semiconductor wafer W is heated by thermal radiation from the heating lamps 252 through the susceptor 230, and the in-plane temperatures of the semiconductor wafer W are measured. In this case, processing gases Ar, H₂, N₂, SiH₄ etc. other than a film forming gas are introduced into the processing container 224, and the pressure is arranged at substantially 10666 Pa, and the semiconductor wafer W is controlled to maintain 445° C. In the figure, the horizontal axis shows measurement positions given that the center position of the semiconductor wafer W with a diameter of 30 mm is 0, and the vertical axis shows temperatures measured at these measurement positions. Also, the graph with black circles shows in-plane temperatures of the semiconductor wafer W and the points indicated by the white circles show temperature of the clamp ring 242. By comparing the result of the experiment shown in FIG. 22 with the result of the experiment shown in FIG. 5 wherein the clamp ring 242 and the susceptor 230 are composed of the same white-colored AIN-based ceramics, it is clear that the temperature of the clamp ring 242 (white circles) becomes higher than the temperature of the center part and its peripheral part (−100 mm to 100 mm) of the semiconductor wafer W, and also the temperatures of the rim part (100 mm to 150 mm, −100 mm to −150 mm) of the semiconductor wafer W show no decrease compared to the case shown in FIG. 14. That is to say, obviously the escaped heat from the rim part of the semiconductor wafer W is supplemented due to the clamp ring 242 receiving more heat for its law thermal radiation transmissivity. Consequently, evenness of the in-plane temperature distribution of the semiconductor wafer W is improved by preventing the temperature of the rim part of the semiconductor wafer W from becoming lower compared to the temperature of the center part and its peripheral part.

In this way, the clamp ring 242 is prevented from absorbing heat from the rim part of a semiconductor wafer W due to the clamp ring 242 composed of black-colored AlN-based ceramics with lower thermal radiation transmissivity than the susceptor 230. Consequently, evenness of thickness of a film formed on a semiconductor wafer W is also improved because the temperature differential within the surface of a semiconductor wafer W caused by a difference in areas that receive thermal radiation can be decreased.

In particular, the effects of application of the present invention are large due to the fact that heat escape from the rim part of the semiconductor wafer W becomes greater as diameter of a semiconductor wafer W becomes longer and thus the temperature differential between the center part and the rim part is likely to increase and also the temperature distribution of a semiconductor wafer W is likely to become uneven.

Further, a thinner susceptor 230 in thickness can be applied for achieving increased effectiveness of heat conduction to a semiconductor wafer W. The susceptor 230 with thickness of 7 mm to 10 mm may be reduced to approximately 1 mm to 7 mm. In this case, the thinner thickness of the susceptor 230 becomes, the more increased effectiveness heat conduction of the susceptor 230 achieves. However, thermal radiation absorptance becomes lower because thermal radiation transmissivity becomes higher, and furthermore, the temperature of the susceptor 230 becomes relatively lower than the temperature of the clamp ring 242 because heat escape from the rim part is increased.

Therefore, in a case that thickness of the susceptor 230 is thinned to approximately 1 mm to 7 mm for example (preferably 3.5 mm to 5 mm), the susceptor 230 composed of black-colored AlN-based ceramics with low thermal radiation transmissivity as well as the clamp ring 242 is effective. Consequently, the temperature differential within the surface of a semiconductor wafer W caused by the thinner susceptor 230 can be decreased, and thus evenness of thickness of a film formed on a semiconductor wafer W can be further improved. Furthermore, in this case, the same effect as in the aforementioned embodiment can be expected. That is to say, also in a case that dissimilar members such as the temperature sensors (TC) 291 and 292 are inserted in the susceptor 230 according to the present embodiment, evenness of the temperature distribution within the surface of a semiconductor wafer W can be improved, evenness of film thickness can be improved, and both resistance values and evenness can be improved.

Meanwhile, in the above embodiment, other than a plurality of the lifter pin holes 236 as relief holes to enable the lifter pins 232 to come in and out, temperature control holes 294 having the same shape as the lifter pin holes 236 can be formed on the susceptor 230 in a manner that each hole 236 and each hole 294 are aligned and equally spaced on a concentric circle as shown in FIG. 23. Consequently, intervals between each hole 236 and 294 become narrower, and also each hole 236 and 294 is equally spaced, and thus thermal radiation from the heating lamps 405 is evenly transmitted through each hole 236 and 294. Thus evenness of the temperature distribution on the rim part of the susceptor 230 can be improved compared to a case that thermal radiation is transmitted only through the lifter pin holes 404 as shown in FIG. 3.

Further, in the above embodiment, a case of a tungsten film formation, by CVD, on a TiN barrier metal formed by sputtering apparatus or by CVD apparatus is explained, but barrier metals and further metal film formation are not limited to this kind. For example, as barrier metals, metal films such as Ti, Ta, W, Mo and silicide or also nitride such as Ti, W, Mo etc. as barrier metals can be used, and a metal film formation can be applied to an aluminum film formation, for example. Also, the present thermal processing apparatus can be applied not only to a film formation on barrier metals in this way, but to a general film forming processing.

Hereinbefore, the preferred embodiments according to the present invention is described with reference to the accompanying drawings, but the present invention is not limited by concerning examples, needless to add. It is obvious that various other changes and modifications may be made by those skilled in the art without departing from the appended claims, and therefore the invention should be understood to include all the above.

As described above, the present invention can provide a thermal processing apparatus whereby evenness of temperature distribution of a wafer W can be improved and consequently evenness of thickness distribution of a thin film formed on an object such as a semiconductor wafer can be improved.

In particular, by a acceptance heating element composed of a material with thermal radiation transmissivity equal to or more than dissimilar members contained in the acceptance heating element, and by the acceptance heating element composed of black-colored AlN-based ceramics with low thermal radiation transmissivity, impacts on temperature distribution of the acceptance heating element such as susceptor, caused by containing dissimilar members, can be decreased, and evenness of in-plane temperature distribution of a semiconductor wafer can be improved.

Further, by an object pressing member composed of a material with lower thermal radiation transmissivity than a acceptance heating element, temperature differential between the acceptance heating element and the object pressing member can be decreased, and the object pressing member can be prevented from absorbing heat from the rim part of a semiconductor wafer, and thus evenness of in-plane temperature distribution of a semiconductor wafer can be improved. Further, by the object pressing member, whose temperature is likely to become relatively lower than the acceptance heating element, composed of black-colored AlN-based ceramics with low thermal radiation transmissivity, temperature differential between the acceptance heating element such as a susceptor and the object pressing member can be decreased, and thus evenness of in-plane temperature distribution of a semiconductor wafer can be improved.

Further, by forming relief holes, which enable a plurality of supporting members for holding an object to be mounted on a acceptance heating element to come in and out, and holes having the same shape thereof on the acceptance heating element in a manner that each hole is aligned and equally spaced on a concentric circle, thermal radiation from a heat source is evenly transmitted through each hole, and evenness of temperature distribution of the rim part of the acceptance heating element such as a susceptor can be improved, and thus evenness of in-plane temperature distribution of a semiconductor wafer can be improved.

What is claimed is:

1. A processing apparatus characterized by comprising:
a processing container for processing a substrate with a processing gas;
a pedestal positioned inside said processing container, for mounting a substrate;
a processing gas feeder for feeding a processing gas to the front surface of said substrate inside said processing container;
an annular substrate-holding member for holding said substrate on said pedestal by holding down a rim of said substrate;
a purge gas feeder for feeding a purge gas to a space formed at the back surface side of said substrate;
a purge gas flow path defined by said substrate holding member, for upwardly inducing said purge gas from said space;
and a gas discharge mechanism for discharging said purge gas from said space in a case that a pressure in said space becomes higher than a pressure outside said space within said processing container by a predetermined value.

2. A processing apparatus according to claim 1, characterized by further comprising a support member for holding an outer circumference of said substrate holding member, wherein said purge gas flow path includes a first flow path passing between said substrate holding member and said substrate and a second flow path passing between said substrate holding member and said supporting member.

3. A processing apparatus according to claim 1, characterized by said gas discharge mechanism comprising:
a discharge hole for discharging said purge gas; and
a valve for opening said discharge hole in a case that the pressure differential between the inside and the outside of said space within said processing container becomes higher by a predetermined value.

4. A processing apparatus according to claim 1, characterized by said gas discharge mechanism comprising:
a valve body with a discharge hole for discharging said purge gas; and
a valve having a valve element which is larger than said discharge hole in diameter, said valve element closing said discharge hole by own weight,
said valve-element weight being adjustable in relation to the dimension of said discharge hole for controlling the pressure differential for said valve to operate.

5. A processing apparatus according to claim 1, characterized in that said gas discharge mechanism discharges said purge gas before the pressure differential between the inside and the outside of said space within said processing container reaches a value for said substrate holding member to be lifted by said purge gas flowing through said purge gas flow path.

6. A processing apparatus according to claim 1, characterized in that said gas discharge mechanism discharges said purge gas after the pressure differential between the inside and the outside of said space within said processing container exceeds a value of pressure loss caused by flow of said purge gas from said space when said substrate is processed.

7. A processing apparatus according to claim 1, characterized in that said gas discharge mechanism is switched to an open condition from a closed condition when the pressure differential between the inside and the outside of said space within said processing container reaches a value between a value of pressure loss caused by flow of said purge gas from said space at substrate processing and a value for said substrate holding member to be lifted by said purge gas flowing through said purge gas flow path.

8. A processing apparatus according to claim 1, characterized by further comprising a gas introducing mechanism for introducing atmosphere outside said space within said processing container into said space in a case that a pressure outside said space within said processing container becomes higher than a pressure inside said space by a predetermined value.

9. A processing apparatus according to claim 8, characterized by said gas introducing mechanism comprising:
a valve body with a introducing hole for introducing atmosphere outside said space within said processing container into said space; and
a valve having a valve element and a shaft, said valve element being larger than said introducing hole in diameter and closing said introducing hole by own weight,
said valve-element weight being adjustable in relation to the dimension of said introducing hole for controlling the pressure differential for said valve to operate.

10. A processing apparatus according to claim 8, characterized by said gas introducing mechanism comprising:
an introducing hole for introducing atmosphere outside said space within said processing container into said space;
and a valve for opening said introducing hole in a case that a pressure outside said space within said processing container becomes higher than a pressure in said space by said predetermined value.

11. A processing apparatus characterized by comprising:
a processing container for processing a substrate with a processing gas;
a pedestal positioned inside said processing container, for mounting a substrate;
a processing gas feeder for feeding a processing gas to a first space formed at the front surface side of said substrate;
an annular substrate-holding member for holding said substrate by holding down a rim of said substrate;
a purge gas feeder for feeding a purge gas to a second space formed at the back surface side of said substrate;
a purge gas flow path defined by said substrate holding member, for introducing said purge gas from said second space to said first space;
an exhaust means for exhausting said first space through a third space formed below said first space and outside said second space;
and a gas discharge mechanism for discharging said purge gas to said third space in a case that a pressure in said second space becomes higher than a pressure in said first space by a predetermined value.

12. A processing apparatus according to claim 11, characterized by further comprising a support member for holding an outer circumference of said substrate holding member, wherein said purge gas flow path includes a first flow path passing between said substrate holding member and said substrate and a second flow path passing between said substrate holding member and said supporting member.

13. A processing apparatus according to claim 8 or claim 12, characterized in that said gas discharge mechanism is formed to communicate through said third space and said second space and has a discharge hole for discharging said purge gas and a valve for opening said discharge hole in a case that a pressure in said second space becomes higher than a pressure in said third space by said predetermined value.

14. A processing apparatus according to claim 11, characterized by said gas discharge mechanism comprising:
a valve body with a discharge hole for discharging said purge gas; and
a valve having a valve element which is larger than said discharge hole in diameter, said valve element closing said discharge hole by own weight,
said valve-element weight being adjustable in relation to the dimension of said discharge hole for controlling the pressure differential for said valve to operate.

15. A processing apparatus according to claim 11, characterized in that said gas discharge mechanism discharges said purge gas before the pressure differential between said second space and said first space reaches a value for said substrate holding member to be lifted by said purge gas flowing through said purge gas flow path.

16. A processing apparatus according to claim 11, characterized in that said gas discharge mechanism discharges said purge gas after the pressure differential between said second space and said first space exceeds a value of pressure loss caused by flow of said purge gas from said second space into said first space when said substrate is processed with a processing gas.

17. A processing apparatus according to claim 11, characterized in that said gas discharge mechanism is swithched to an open condition from a closed condition when the pressure differential between said second space and said first space reaches a value between a value of pressure loss caused by flow of said purge gas from said space at substrate processing and a value for said substrate holding member to be lifted by said purge gas flowing through said purge gas flow path.

18. A processing apparatus according to claim 11, characterized by comprising a gas introducing mechanism for introducing atmosphere inside said third space into said second space in a case that a pressure in said third space becomes higher than a pressure in said second space by a predetermined value.

19. A processing apparatus according to claim 18, characterized by said gas introducing mechanism comprising:
a valve body with a introducing hole for introducing atmosphere in said third space into said second space; and
a valve having a valve element and a shaft, said valve element being larger than said introducing hole in diameter and closing said introducing hole by own weight,
said valve-element weight being adjustable in relation to the dimension of said introducing hole for controlling the pressure differential for said valve to operate.

20. A processing apparatus according to claim 18, characterized in that said gas introducing mechanism is formed to communicate through said third space and said second space and comprises:
an introducing hole for introducing atmosphere in said third space into said second space;
and a valve for opening said introducing hole in a case that a pressure in said third space becomes higher than a pressure in said second space by predetermined value.

21. A processing apparatus wherein an object is mounted on a acceptance heating element inside a processing container supplied with a processing gas and then said object is heated by thermal radiation from a heat source through said acceptance heating element, characterized in that said acceptance heating element is composed of a material with thermal radiation transmissivity equal to or lower than those of dissimilar members contained in said acceptance heating element.

22. A processing apparatus wherein an object is mounted on a acceptance heating element inside a processing container supplied with a processing gas and then said object is heated by thermal radiation from a heat source through said acceptance heating element, characterized in that said acceptance heating element is composed of black-colored AlN-based ceramics.

23. A processing apparatus wherein an object is mounted on a acceptance heating element inside a processing container supplied with a processing gas and then said object is heated by thermal radiation from a heat source through said acceptance heating element while a ring-shaped object pressing member holds this object by the rim part, characterized in that said object pressing member is composed of a material with lower thermal radiation transmissivity than said acceptance heating element.

24. A processing apparatus wherein an object is mounted on a acceptance heating element inside a processing container supplied with a processing gas and then said object is heated by thermal radiation from a heat source through said acceptance heating element while a ring-shaped object pressing member holds this object by the rim part, characterized in that said object pressing member is composed of black-colored AlN-based ceramics.

25. A processing apparatus wherein an object is mounted on a acceptance heating element inside a processing container supplied with a processing gas and then said object is heated by thermal radiation from a heat source through said acceptance heating element, characterized in that relief holes, which enable a plurality of supporting members for supporting said object to be mounted on said acceptance heating element to come in and out, and holes having the same shape thereof are formed on said acceptance heating element in a manner that each hole is aligned and equally spaced on a concentric circle.
